(19) United States
(12) Patent Application Publication
(10) Pub. No.: US 2025/0358905 A1
(43) Pub. Date: Nov. 20, 2025

(54) METHOD AND APPARATUS FOR THERMAL PROCESSING USING PULSED RESISTANCE HEATING

(71) Applicant: PulseForge. Inc., Austin, TX (US)

(72) Inventors: Kurt A. Schroder, Coupland, TX (US); Douglas K. Jackson, Round Rock, TX (US); Vikram Shreeshail Turkani, Austin, TX (US)

(21) Appl. No.: 19/210,818

(22) Filed: May 16, 2025

Related U.S. Application Data
(60) Provisional application No. 63/648,518, filed on May 16, 2024.
(60) Provisional application No. 63/794,150, filed on Apr. 24, 2025.

(51) Int. Cl. H05B 3/00; H01L 21/67

(52) U.S. Cl. CPC H05B 3/0004; H01L 21/67103

(57) ABSTRACT

A carrier for temporarily carrying an electronics structure for thermal processing and corresponding system and methods for using the same. The carrier includes an electrically conductive layer (“ECL”) that defines at least one current path through which a current can travel. The carrier is configured to be connected to a current source so pulsed current is passed through the current path to generate heat in a working area of the carrier. The carrier is configured to carry an electronics structure near the working area. When the current source is used to generate heat in the carrier, thermal processing of the electronics structure is performed. A temperature of the electronics structure and the carrier is regulated by controlling the intensity, duration, and period of the pulsed current.

### CROSS-REFERENCE TO RELATED APPLICATIONS

This application claims the benefit of U.S. Provisional Applications No. 63/648,518, filed May 16, 2024, and No. 63/974,150, filed Apr. 24, 2025, each of which is hereby incorporated herein by reference in its entirety.

### FIELD

The present disclosure relates to processing electronics structures and, more specifically, to processing electronics structures carried on carriers with one or more electrically conductive heating layers.

### BACKGROUND

Processing electronics structures (e.g., electronics devices and/or components thereof) at high working temperatures can yield more efficient and/or effective performance in many circumstances. However, the materials used in electronics structures are susceptible to irreversible damage and/or failure if they sustain an average temperature above a maximum steady-state threshold for the materials. Thus, relatively expensive, temperature-resistant components are frequently used in combination with components that require high temperatures to process (e.g., polyimide, or “PI,” a high-temperature polymer). Additionally, processing components of electronics devices for long periods of time in high-temperature environments (e.g., in ovens or on heat plates) requires significant amounts of sustained energy, which can be inefficient and costly. Further, in certain high-temperature processing scenarios, such as the curing of PI, even high-temperature processing can be difficult to control due to the formation of byproducts (e.g., vapors) that interfere with the processing (e.g., the entrapment of bubbles that inhibit the formation of a uniform layer of cured resin).

### SUMMARY

In one aspect, a carrier for temporarily carrying an electronics structure for processing comprises an electrical contact side of the carrier and a working side of the carrier opposite the electrical contact side. The carrier additionally comprises an electronics structure support surface on the working side configured to support the electronics structure temporarily for processing of the electronics structure. The carrier additionally comprises a carrier body having a first side on the electrical contact side of the carrier and an opposite second side on the working side of the carrier. The carrier body has a peripheral edge between the first and second sides, a first electrical contact on the electrical contact side and supported by the carrier body and a second electrical contact on the electrical contact side and supported by the carrier body. The carrier body additionally has a first resistance heating current passage on the working side of the carrier and supported by the carrier body. A first current pathway extends over the peripheral edge of the carrier body from the first side to the second side. The first current pathway electrically couples the first resistance heating current passage with the first electrical contact. A second current pathway extends over the peripheral edge of the carrier body from the first side to the second side. The second current pathway electrically couples the first resistance heating current passage with the second electrical contact. The first resistance heating current passage is configured to generate heat via current passed through the first resistance heating current passage via the first and second electrical contacts.

Other objects and features will be in part apparent and in part pointed out hereinafter.

### BRIEF DESCRIPTION OF THE DRAWINGS

Aspects of the present disclosure, including various embodiments, further objects, and advantages thereof, will best be understood by reference to the following detailed description when read in conjunction with the accompanying drawings, wherein:

FIG. 1 is a schematic diagram of a resistive electronics structure processing system in accordance with one embodiment;

FIG. 2 is a graph of a temperature of an electronic component as a function of time during use of the electronics structure processing system;

FIG. 3 is a flow chart of a method of using the system for curing a layer of thermosetting polymer;

FIG. 4 is a flow chart of a method of using the system for thermally processing and debonding an electronics structure that is temporarily bonded to a carrier;

FIGS. 5A-5B are schematic diagrams of a resistive electronics structure processing system in accordance with another embodiment;

FIGS. 6A-6B are top and bottom views of a carrier used with the system shown in FIGS. 5A-5B;

FIGS. 7A-7B are top and bottom views of an alternative carrier for use with the system shown in FIGS. 5A-5B;

FIG. 8 is a schematic diagram of a resistive electronics structure processing system in accordance with another embodiment;

FIG. 9 is a schematic diagram of a resistive electronics structure processing system in accordance with another embodiment;

FIG. 10 is a schematic diagram of a resistive electronics structure processing system in accordance with another embodiment;

FIG. 11 is a schematic diagram of an alternative carrier stack in accordance with another embodiment;

FIG. 12 is a schematic diagram of an alternative carrier stack in accordance with another embodiment;

FIG. 13 is a schematic diagram of an alternative carrier stack in accordance with another embodiment;

FIG. 14 is a schematic diagram of a resistive electronics structure processing system in accordance with another embodiment;

FIGS. 15A-15B are top and bottom views of a carrier in accordance with another embodiment;

FIG. 16 is a schematic diagram of a resistive electronics structure processing system for use with the carrier of FIGS. 15A-15B;

FIG. 17 is a schematic diagram of another resistive electronics structure processing system for use with the carrier of FIGS. 15A-15B;

FIG. 18 is a schematic diagram of a rotary resistive electronics structure processing system in accordance with another embodiment;

FIG. 19 is a perspective view of the carrier of the system of FIG. 18;

FIG. 20 is a cross-sectional schematic diagram of the carrier of FIG. 19;

FIG. 21 is a schematic diagram of a resistive electronics structure processing system in accordance with another embodiment;

FIG. 22 is a schematic diagram of an alternative carrier stack in accordance with another embodiment; and

FIGS. 23A-23C are schematic diagrams of an alternative carrier in accordance with another embodiment.

Corresponding reference characters indicate corresponding parts throughout the drawings.

### DETAILED DESCRIPTION

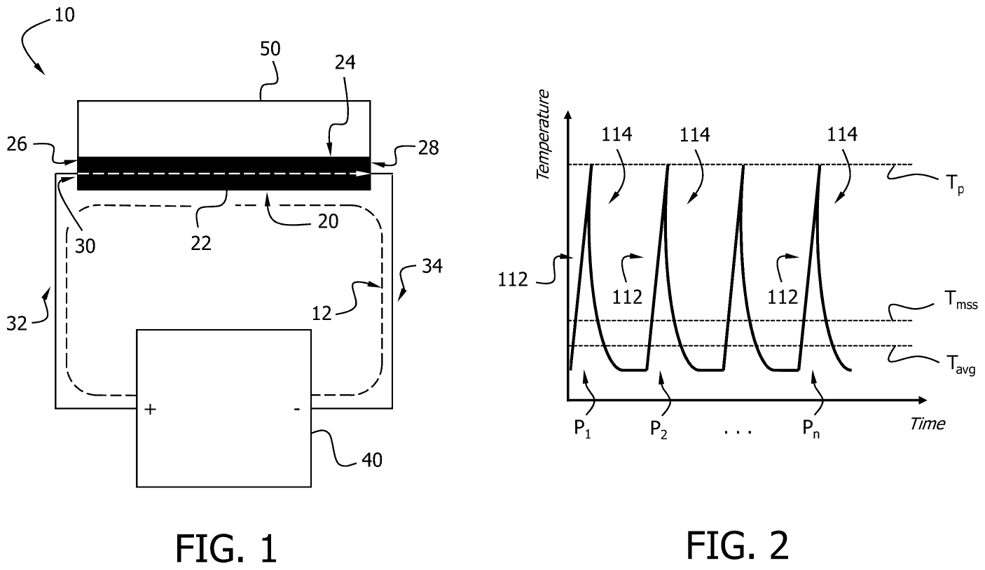

An example of a resistive electronics structure processing system is shown schematically in FIG. 1 with reference number 10. The system 10 is configured to includes a movable, reusable carrier 20 that is configured to carry a layer 50 of a thermally curable material (generally, a processing substrate). The carrier 20 includes an electrically conductive layer (“ECL”) 22 that has resistive characteristics and therefore generates heat when current is directed through the ECL. Thus, the carrier 20 is understood to be an electrically conductive carrier, which can comprise only the ECL or may include other constituent materials or components such as a carrier body and/or one or more dielectric layers to isolate the ECL from other electrically conductive elements. It will be appreciated that when ECL, ECL-coated carrier, or similar is used herein, that broadly means an electronically conductive carrier.

As described in greater detail below, the system 10 is configured to receive the carrier 20 to create a circuit between the carrier and a current source 40. The current source 40 that is configured to generate a sequence of current pulses which, when passed through the ECL 22, generate pulses of heat at a working surface 24 defined by a working area of the ECL across which heat is actively transferred to the electronics structure. The current pulses can be controlled to yield rapid, efficient thermal processing due to controlled, localized heating in areas near the working surface 24. It will be appreciated that the term “thermal processing,” as used herein, encompasses any process that needs heat to progress, for example: drying, sintering, ablating, chemical reaction initiation, chemical reaction modulation, phase change initiation, phase change modulation, melting, crosslinking (e.g., polymerization), activation, etc. Accordingly, curing a thermosetting polymer located on the working surface 24 is one example of thermal processing.

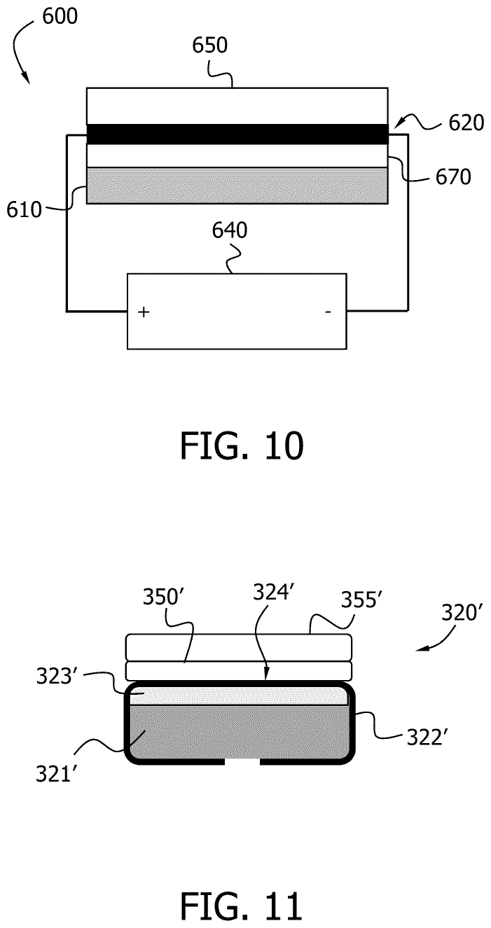

It will be appreciated that the ECL 22 can comprise metal, metal alloys, semiconductors, ceramic, carbon, polymer, or other suitable materials with electrical conductivity. In some situations, such as the example shown above in FIG. 1, the processing substrate can be the curing layer 50 that contains a thermally curable material, though other kinds of processing substrates can be processed by the system instead of (or in addition to) the curing layer shown in FIG. 1. In some embodiments, the ECL is selected to have a coefficient of thermal expansion (CTE) that is closely matched to the carrier to minimize deformation and/or other types of damage to the carrier 20 and/or one or more electronics device components (broadly, electronics structures) carried by the carrier when the carrier is heated and/or cooled. The carrier 20 is made of a dielectric material that is thermally stable at high temperatures. It is contemplated that the carrier can alternatively be coated with a dielectric material on at least one surface, as will be described in greater detail below in connection with FIGS. 10-13, for example. Together, the ECL-coated carrier 20, the processing substrate 50, and any other devices or materials attached to either of these components (generally, the carrier and all components carried by the carrier) can be referred to as a “stack” or a “carrier stack.” The ECL 22 includes a first electrical contact 26 and a second electrical contact 28, which define a circuit path (or “circuit pathway”) 30 therebetween. More specifically, when the first and second electrical contacts 26, 28 are connected to circuitry (e.g., to form a complete electrical current), current travels across the circuit path 30.

Referring still to FIG. 1, the system 10 additionally includes a current source 40 (e.g., a pulsed current source) that is operatively connected across the ECL 22 to define a circuit 12. When the current source 40 delivers a pulse of current through the circuit path 30 of the ECL 22, the ECL may be heated through a process known as resistance heating. Resistance heating is also known as joule heating, ohmic heating, or I2R heating since the heating rate is proportional to the square of the current through the layer times its electrical resistance. Since the curing layer 50 is in thermal contact with the ECL at the working surface 24, the curing layer is heated by conduction from the ECL. As described in greater detail herein, the heat generated by the system can be controlled to thermally process the curing layer (and/or other processing substrates, more broadly) in sequences that are able to process the curing layer more efficiently and significantly faster than steady-state heating environments provided by equipment such as ovens or hot plates.

In particular, the current source 40 can be modulated (e.g., by generating a series of one or more short pulses of current) to heat localized regions of the curing layer to temperatures significantly above a maximum steady-state temperature (Tₘₛₛ) for the system (generally, the maximum steady-state temperature is the maximum temperature at which the system 10—or a component thereof that is susceptible to overheating—can be sustained without causing damage to the curing layer or adjacent layers in the system) for very short periods of time without causing damage to the system that typically occur when higher temperatures are sustained for comparatively longer periods of time. For example, portions of the curing layer 50 can be briefly heated to peak temperatures Tₚ around 100° C. to 200° C. greater than a typical Tₘₛₛ for the material. Thus, as shown graphically in FIG. 2, the system 10 can be operated according to parameters that maintain an average local temperature Tavg below the maximum steady-state value Tₘₛₛ while also providing short pulses of current that rapidly heat the ECL 22 and nearby portions of curing material 50 to high temperatures in a localized area to enable rapid curing. For example, the duration of the high-temperature state of the material can be selected as a function of the difference in temperature between the high-temperature state and the maximum steady state temperature. In certain conditions, the rapid curing can occur in sequential patterns as smaller sub-layers of the curing layer are heated and cured directionally outward from the ECL (e.g., from regions nearest the working surface 24 of the ECL 22 to regions farthest away from the ECL). This sequential curing pattern can be analogized to a zipper, which establishes a secure connection incrementally in one direction as the zipper is engaged. Thus, this curing process can alternatively be referred to as “zipper curing.”

It will be appreciated that elevating the temperature at which curing layers are held generally causes a significant reduction in the overall curing time of materials in the curing layer because the thermal processing rate of curing materials increases exponentially with the temperature at which the curing materials are held. For reasons discussed in greater detail below, the total amount of energy needed to cure the curing materials can also be reduced when the curing materials are cured quickly. While elevating the temperature to accelerate processing cycles has apparent economic advantages, the processing temperature is not unlimited, as sustained high temperatures can damage the curing material of layer 50 and/or other portions of the carrier stack that have a comparatively low maximum steady-state temperature Tₘₛₛ. Accordingly, it will be appreciated that the current source 40 is pulsed in patterns that generally comprise a rapid heating phase 112, during which at least a portion of the curing layer 50 is elevated to a peak temperature Tₚ above the steady-state maximum value Tₘₛₛ for a very brief period, and a cooling phase 114, in which heat dissipates outward to regulate the local average temperature Tavg over longer periods. The duration and the period of the pulses are controlled to ensure that no components are held at temperatures above their respective maximum steady-state values.

It should be noted that during thermal processing, the maximum steady-state temperature of processing substrates may increase as the materials in the substrates are thermally processed. For example, if a curing layer contains solvent, then the solvent is removed (e.g., dried) prior to subsequent thermal processing steps (e.g., curing). During the drying step, the maximum steady-state temperature is generally lower than during the later thermal processing steps occurring after the solvent is completely dried. Thus, the pulsed current source 40 can be modulated during operation to accommodate several discrete processing operations for the same material (e.g., drying and curing) at different peak and average temperatures as portions of the material transition from a first (e.g., lower) maximum steady-state temperature to a second (e.g., higher) maximum steady-state temperature that can be exposed to higher average temperatures.

Although it is generally undesirable to expose processing substrates to sustained temperatures that exceed the maximum steady-state temperature for a significant period of time, when a periodic (e.g., pulsed) current source is used, a material may be heated significantly above the traditional threshold temperatures (e.g., 200° C. above the maximum steady-state value) for very brief amounts of time, provided that the material is allowed to cool beneath the threshold to maintain an average temperature that remains beneath the destructive threshold, as is generally shown in FIG. 2. It has been determined that the time a material may be held above the maximum steady-state temperature without causing damage is generally inversely related to the degree to which the temperature of the material exceeds the maximum steady-state temperature during the heating cycle. In general, significant reductions in processing time can be realized by the system when the current source is pulsed for durations between 10 microseconds and 100 milliseconds. For example, pulses can operate between 100 microseconds and 10 milliseconds in typical applications. For further effectiveness, the timing of the heating phase 112 and the cooling phase 114 can be optimized (e.g., minimized) so that temperature transitions occur as quickly as possible. Stated differently, in some applications, the material can be heated very quickly and then cooled very quickly with intense, localized pulses. The rapid heating and rapid cooling of the material can effectively maximize the amount of time spent at the upper and lower extremes as compared to transitional temperatures closer to the maximum steady-state value. Since the effectiveness of thermal processing generally increases exponentially with temperature, keeping the material at a comparatively high processing temperature for as much time as possible during each cycle without causing damage generally results in a processing cycle efficiency that significantly exceeds the efficiency of steady-state operation where temperatures are held around the maximum steady-state value for the material.

Rapid heating can be accomplished relatively straightforwardly by sending one or more pulsed currents through the ECL 22 using the current source 40 (e.g., a power source and controller). With currently available resistive equipment and methods, cooling cannot necessarily occur as rapidly or efficiently as heating. Accordingly, as is illustrated in FIG. 2, while each heating phase 112 occurs rapidly with relatively minimal diminishing returns, each cooling phase 114 may see diminishing returns that may demand additional time delays (e.g., a pulse delay interval) after the material has reached a lower threshold temperature to ensure the average temperature is sufficiently below the maximum steady-state temperature to enable substantially damage-free operation in accordance with the principles described herein.

Of course, the curing layer 50 may not fully cure in a single rapid heat/cool cycle, in which case only a portion, or sub-layer, may cure during each discrete pulse. In this case, the heating and cooling cycle can be repeated multiple times until the curing layer is fully cured (e.g., in tiered sub-layers). For example, the pulsed current source 40 can be controlled so that thermal energy gradually permeates deeper into the curing layer with each successive pulse relative to the ECL. In practice, this means the heating of the curing layer can be accomplished, for example, by repetitively pulsing and repetitively cooling the material in controlled cycles until the entire layer is cured. During this process, the average temperature of uncured and not-yet-dried portions of the curing layer can be held below their maximum steady-state temperature by controlling the intensity and duration of the pulses and the interval between the pulses such that heat only travels deeper into the curing layer once the prior sub-layers of the curing material are sufficiently dried and cured.

The temperature of a curing layer over multiple heating and cooling cycles is qualitatively shown in FIG. 2. During processing, the average temperature of the curing layer is held below the maximum steady-state temperature of the curing layer. This protects the parts of the system and materials placed on the system (including the curing layer) from being damaged by sustained high temperatures. The average temperature of the curing layer during processing can be monitored using a pyrometer, though it is contemplated that the average temperature can be monitored based on the temperature of other components in the system and using other equipment or methods without departing from the scope of the present disclosure (e.g., by calibrating and monitoring the intensity of the currents generated by the current source). For example, it will be appreciated that the resistance of the ECL 22 generally increases with as its temperature increases. By monitoring the current through the ECL for a given voltage, its resistance can be calculated, and thus, the temperature of the ECL may be interpolated. By combining that information with a heat diffusion simulation, such as SimPulse®, (PulseForge, Austin, TX USA), one may infer the temperature throughout the entire stack before, during, and after each pulse of current through the ECL.

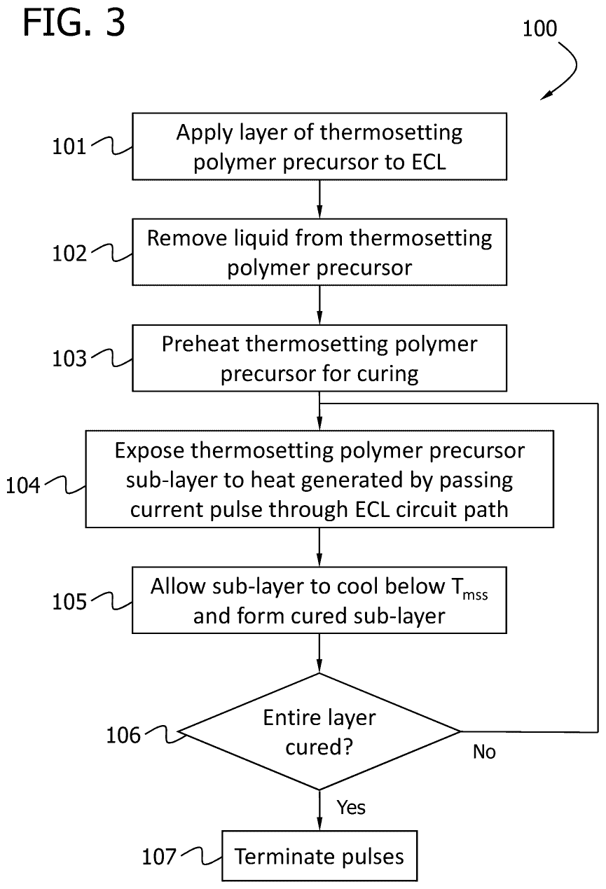

An example of a curing process performed by the system 10 is shown in the flow chart of FIG. 3 as generally indicated at reference number 100. The method 100 includes several steps. The process may begin by applying a layer of thermosetting polymer precursor (curing layer 50) to the ECL 22 of the carrier 20 (step 101). Liquid is then removed from the thermosetting polymer precursor (step 102), e.g., to prepare the thermosetting polymer precursor for curing. In a subsequent step, the polymer precursor is preheated for the curing (step 103). Then, the curing loop (steps 104-106) may begin. In step 104, the current source 40 is activated to generate a current pulse through the ECL 22. This exposes a sub-layer of the thermosetting polymer precursor to heat generated by the ECL. In particular, the first pulse will heat a sub-layer closest to the working surface 24 of the ECL. It will be appreciated that the heated sub-layer is heated to Tₚ during this step. As will be described in greater detail below, in many situations, it is important that the heating provided across the working surface 24 be substantially uniform (e.g., within +20% of a target heating rate in J/cm², and more desirably within +10%) to avoid heating imbalances that can result in critical overheating and/or underheating of portions of the curing layer and, in some cases, to reduce negative side-effects associated with uneven thermal expansion, which can result in curing irregularities as each sub-layer is cured. In step 105, the current source 40 is at least partially deactivated so that the heated sub-layer is allowed to cool until the average temperature Tavg is brought below Tₘₛₛ so the sub-layer fully cures without sustaining damage. The delay additionally allows gaseous byproducts (e.g., water vapor) from the curing process to travel away from the sub-layer so that it does not interfere with the curing of subsequent sub-layers. In step 106, a determination is made (e.g., by a controller associated with the current source 40 or, more broadly, any processor coupled to a tangible, non-transitory storage medium with instructions that allow the processor to make the determination) whether the entire layer 50 of the thermosetting polymer precursor has been cured. If the layer is not entirely cured, steps 104-106 are repeated so one or more subsequent sub-layers can be cured. If the entire layer is determined to be cured, in step 107, the pulses are terminated.

One example of a sequential curing process involves the conversion of polyamic acid to polyimide through the process of imidization. This thermally driven process generates water vapor. The gaseous products of the imidization reaction can be generated in a high concentration adjacent the sub-layer that is being cured by the heat generated from each individual pulse. Because the curing material is cured incrementally in one direction (e.g., from the ECL toward the free surface), all portions of the curing layer closer to the free surface, being less thermally processed, are less susceptible to entrapping resultant water vapor near the recently formed sub-layer. Consequently, this directional curing, colloquially termed “zipper curing” due to its directionality, creates a more reliable path for vapors to travel outward from the curing layer without as much impedance by portions of the curing layer located farther outward from the ECL. Moreover, the pulse intensity and timing between pulses can be controlled to further facilitate the outward travel of resultant gaseous product. In sum, the above advantages are made possible due to the combination of the pulsed heating and continuous cooling of the curing layer. With this process, the curing of polyimide can be accomplished in minutes or even seconds, versus hours with continuous, steady-state processes that are prone to non-uniform curing defects and undesirable entrapment of gaseous product.

A related process may also be carried out in the above example after the polyamic acid is deposited but prior to the imidization stage so that solvent can be evaporated following deposition and prior to curing.

The above-described equipment process differs from a steady-state thermal curing equipment and processes (e.g., involving curing ovens or standard hot plates) in that the directed heating from the ECL toward the curing layer produces a tiered curing phenomenon which progresses from the ECL side toward the free surface of the curing layer, resulting in a sequential curing of sub-layers in this direction. In contrast, thermally processing a thin film using a steady-state heating source results in the entire film being maintained at the same temperature, and the thermal processing of the curing layer is uniform.

The sequential thermal processing of the curing layer from the ECL side to the free surface side has several important implications. For example, many thermal processes generate some amount of gas. When the average temperature of the curing material during thermal processing is too high, the gas generation can be high enough to cohesively destroy the film being processed. Additionally, as many types films are processed, they become more impervious to the diffusion of gas, so thermal processing of thick layers of material can be problematic as vapors become trapped and inhibit a uniform curing profile. In contrast, the pulsed heating and cooling cycles enable the processing of the yet-uncured material nearest the heat-generating ECL.

Another implication of the process is that it has the ability to produce thin films with controlled crystallinity. Continuous or steady-state heating processes are inherently slow and can produce inconsistent crystallinity in the cured material as a consequence of this slowness. By contrast, the temperature-controlled processes described herein can be several orders of magnitude faster. This facilitates orderly crystallization and prevents runaway crystallization, thereby producing a more uniform product. This resulting uniformity can be advantageous in various fields, such as the production of batteries or photovoltaic materials.

Another implication of this process is that multiple curing layers may be deposited and cured in two or more discrete steps. The additional curing layers may be composed of the same or different materials as the first curing layer. This process permits very thick depositions of materials that previously could not be formed in thick layers in a relatively short timeframe. As best seen in FIG. 13 and discussed in greater detail below in connection therewith, it will be appreciated that the above-described process can be performed multiple times to deposit (generally, apply) and cure multiple (e.g., two or more) discrete curing layers in accordance with the same principles. Layers of other functional materials may be deposited between layers of curing materials as well (more broadly, multiple different components can be carried by the carrier simultaneously in multiple layers), and it will be appreciated that the various layers may be selectively deposited by universal equipment depending on the characteristics of each product to be processed by the equipment. This means that a wide variety of multilayer devices, such as a thin film circuit boards, may be additively built up by selectively depositing and thermally processing dielectric, conductive, and semiconductive materials.

Yet another implication of this process is that the first and subsequent curing layers can each be temporarily heated to a temperature above their maximum working temperature. Not only does this decrease the total time of the curing process for each layer, but even thermally fragile materials can be attached to the stack adjacent the materials that are being processed at high temperatures without causing damage due to the controlled heat transfer principles described herein. The localized concentration of high temperatures provided by the processes described herein would not be possible with standard steady-state heating sources.

Variants of ECL carrier and pulsed current source, as discussed herein, can be adapted for processing and/or releasing an electronics structure that is temporarily bonded to the ECL-coated carrier, e.g., with an adhesive (broadly, a “temporary bonding layer”), after the performance of other manufacturing stages. After the other manufacturing stages are completed, the pulsed current source can be activated to pass electric current through the ECL and heat adhesive at the boundary (or “interface”) between the ECL and the adhesive to a temperature high enough to thermally decompose the adhesive at the interface. The result is that the adhesive bond is loosened (broadly, “weakened”) between the carrier and the device. For example, the maximum power and/or the duration and interval of the pulsed current can be increased above the thresholds discussed above. This controlled overheating in the region around the ECL can be used to release devices from the carrier after processing is complete. Thus, the controlled release can broadly be understood as one type of processing for which the system can be used.

It will be appreciated that the maximum power, duration, and interval of the pulses of current can be controlled to minimize excessive exposure to temperature-sensitive components in the ECL carrier or portions of the electronics structure supported by the ECL carrier via the temporary bonding layer. Thus, the overheating can be controlled to enhance reusability of the ECL carrier and to reduce the risk of damage to processed devices. In this way, the ECL carrier provides a stable temporary support for the device during processing.

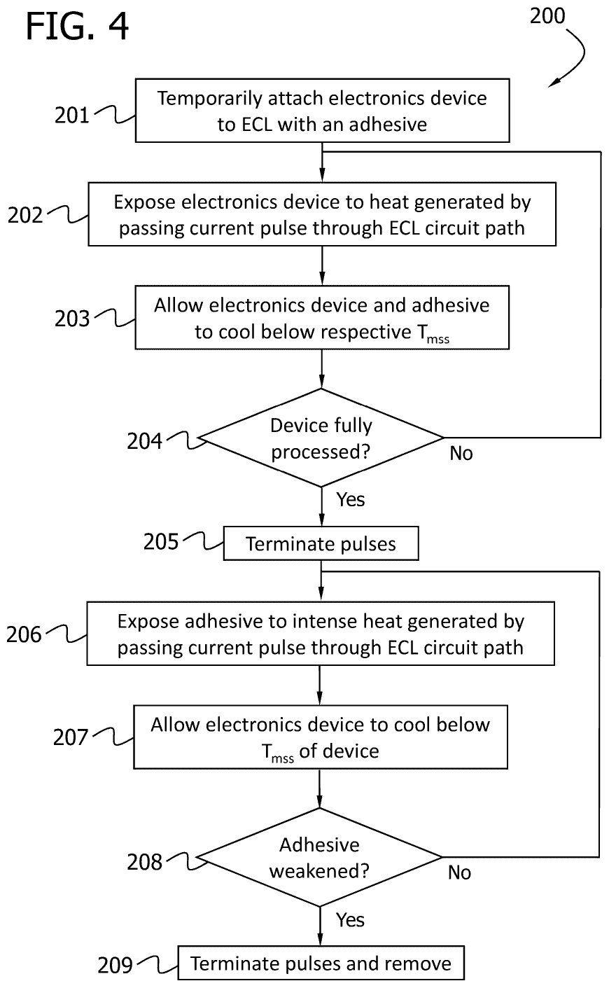

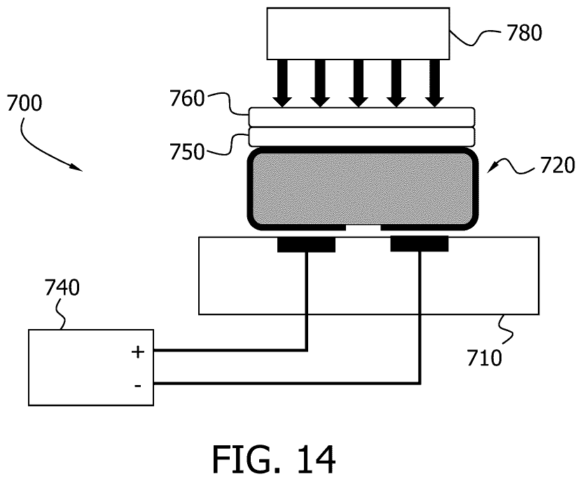

Another example of a process that can be performed by the system 10 is shown in the flow chart of FIG. 4 as generally indicated at reference number 200. The method 200 is directed to processing an electronics structure adhesively bonded to the carrier and subsequently debonding the adhesive (such as the carrier stack shown schematically in FIG. 14 in connection with system 700). It will be appreciated that the process 200 can be used after a process for thermally curing the adhesive in accordance with the steps of process 100. The process 200 may begin by temporarily attaching an electronics structure to the ECL with an adhesive. The adhesive may be thermally stable up to a temperature of approximately 200° C. or, in some cases, around or above 300° C. for organic adhesives. For inorganic adhesives, even higher temperatures (e.g., above around 400° C.) may be sustained. A thermal processing loop (steps 202-204) may then begin. In step 202, the current source is activated to generate a pulse through the ECL 22. This exposes some or all of the portions of the electronics structure to be processed to be heated to a peak temperature Tₚ. It will be appreciated that heat is transferred through the adhesive to heat the electronics structure. In step 203, the current source is at least partially deactivated so that the carrier stack is allowed to cool until the average temperatures of the electronics structure and the adhesive Tavg are brought below their respective Tₘₛₛ to prevent damage to the components on the carrier stack. In step 204, a determination is made (e.g., by a controller associated with the current source 40 or, more broadly, any processor coupled to a tangible, non-transitory storage medium with instructions that allow the processor to make the determination) whether the processing has been completed. For example, the determination could entail checking whether a predetermined number of pulses known to result in processing have been generated, though it is contemplated that active monitoring of one or more characteristics of the electronics structure may also be employed. If it is determined that the processing is not complete, steps 202-204 are repeated.

If it is determined that the processing is complete, the processing pulses are terminated (step 205). Then, after any optional processing steps are completed, in steps 206-208 a second pulsing loop is performed to weaken the adhesive so the electronics structure can be debonded from the carrier. In step 206, the current source is activated to generate a high-intensity pulse through the ECL 22. This exposes the adhesive to intense heat around the working surface 24, and at least a portion of the adhesive achieves a high peak temperature Tₚ (e.g., around 1,000° C. for an inorganic adhesive) that is substantially higher than a destructive threshold temperature for the adhesive. In step 207, the current source is at least partially deactivated so that the carrier stack is allowed to cool to ensure that the average temperature of the electronics structure remains below its respective Tₘₛₛ to prevent damage to its components. In step 208, a determination is made whether the adhesive is sufficiently weakened. If it is determined that the adhesive is not sufficiently weakened, steps 206-208 are repeated. If it is determined that the adhesive is sufficiently weakened, the pulses are terminated and the electronics structure is removed (generally, debonded) from the carrier.

It will be appreciated that the example processes described above in connection with FIGS. 3-4 can be used, where applicable, with the additional examples of carriers and carrier stacks described below. Thus, it will be appreciated that additional and/or simultaneous steps may be added to the above-described processes without departing from the scope of the present disclosure. Likewise, it will be appreciated that additional equipment can be used in conjunction with the current source and additional materials and/or layers may be added to the carrier without departing from the scope of the present disclosure.

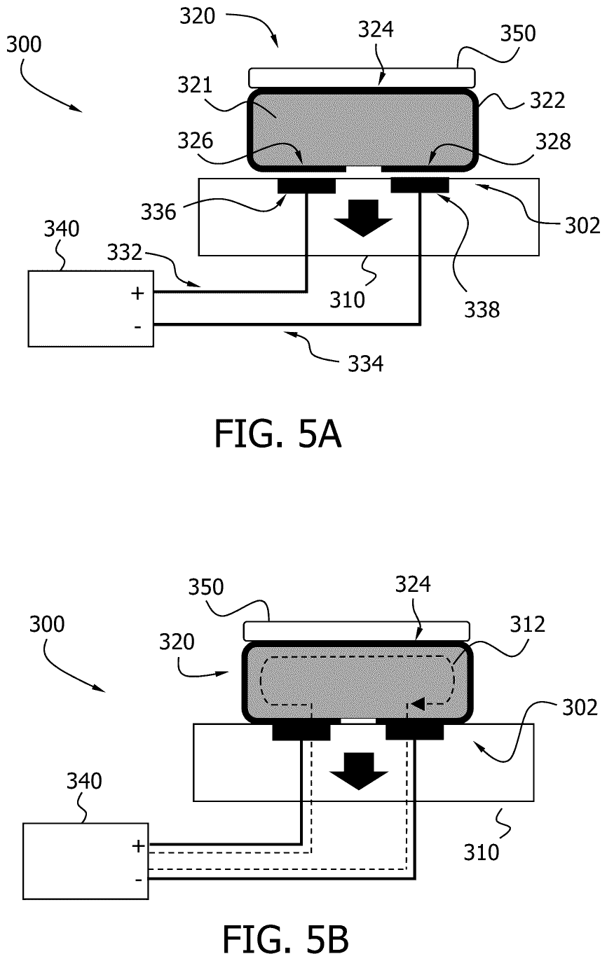

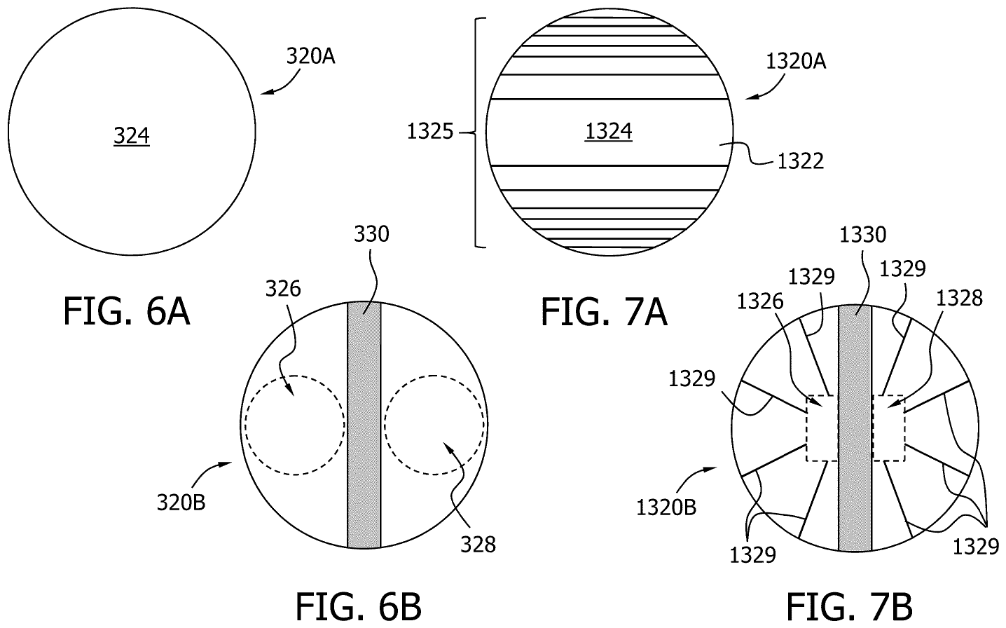

How to electrically connect the pulsed power source to the ECL is nontrivial in the processes described above. The current through the ECL may be hundreds or even thousands of amps, while the ECL may only be hundreds of nm to a few microns thick. FIGS. 5A and 5B schematically provide an example of a system 300 that includes an ECL carrier 320 that is adapted for connectivity to a pulsed current source 340 using a flat, circular wafer 321 (broadly, a “carrier body”) that acts as a dielectric support for an ECL 322, which is deposited (broadly, carried) on the carrier body. As shown in FIGS. 5A and 5B, the ECL 322 wraps around (e.g., at least partially envelops) the carrier body 321, and electrical contact between the pulsed current source and the carrier wafer is established on the back (or contact) side of the carrier wafer via a first electrical contact 326 and a second electrical contact 328. There is an electrical break (see reference number 330 in FIG. 6B) in the ECL 322 on the contact side of the carrier wafer which defines a current path through the ECL between the first and second electrical contacts 326, 328. The ECL carrier 320 is supported by a support 310 (e.g., a “platform” or “stage”). In particular, the support 310 of FIGS. 5A and 5B is a vacuum chuck that is configured to apply vacuum to the ECL carrier 320 to hold the ECL carrier at a retaining location 302 (broadly, a holding location). The vacuum chuck provides the necessary force to prevent arcing between the electrical contact interconnects 336, 338 (broadly, “electrical contact interfaces”) of the vacuum chuck and the ECL. This configuration allows for large-area contacts (e.g., the first and second contacts 326, 328) to enhance the reliability of the electrical connection.

The support 310 is operatively connected to the current source 340. In particular, the system 300 includes circuitry that provides a first current path 332 connecting the current source 340 a first electrical contact interconnect 336 (broadly, a first electrical contact interface) located near the holding location 302 and likewise provides a second current path 334 connecting a second electrical contact interconnect 338 (broadly, a second electrical contact interface) located near the holding location 302 to the current source. The first and second electrical contact interconnects 336, 338 are flush with a surface of the support 310 (thus, they form at least part of a support surface for supporting the carrier 320). As best seen in FIG. 5B, when the first and second electrical contacts 326, 328 contact the first and second interconnects 336, 338, a circuit 312 is formed which allows the current to pass through the ECL 322. Thus, a curing layer 350 located on a working surface 324 of the ECL can be reliably heated in accordance with the processes described above.

In practice, because uniformity in heat (e.g., to within ±20% or ±10% of a target intensity in W/cm²) is often desired across an entirety of the working surface 324 to perform the above-described heating processes consistently and reliably, it can be desirable to have substantially uniform I2R heating across the ECL 322 so that a spatially uniform amount of resistance heating is provided across the ECL along the working surface when current pulses are delivered from the current source. More generally, even in situations where slight differences in uniformity of heating is desired across different portions of the ECL, it is important to control the current density to yield effective results without under- or over-heating components. This generally means that both the sheet resistance R across the ECL is closely controlled (e.g., substantially uniform or with small biases to ensure substantially uniform heating) and the current density I across the ECL is likewise closely controlled. In the case when the substrate is rectangular, such as a panel, uniformity of these characteristics can be easier to regulate. However, in cases where the substrate has a circular profile, such as with the wafer 321, current density distributions can be more difficult to control.

FIGS. 6A-6B show how a back side 320B (or contact side) of the ECL carrier 320 is configured to promote uniform current density across the working surface 324 located on a front side (or working side) 320A of the ECL carrier 320. In particular, the first and second electrical contacts 326, 328 (which are indicated in dashed lines as sites that are configured to engage the first and second interconnects 336, 338 of the support 310 when the ECL carrier 320 is held in the holding site 302) are shaped and sized to promote a sufficiently uniform current density distribution across the working surface 324 to achieve a desired result during thermal processing. As shown in FIGS. 6A and 6B, the first and second electrical contacts 326, 328 are substantially circular. Although circular cross-sectional contact regions are shown in the present example, it will be appreciated that other shapes and other geometries (e.g., oval, semicircular, rectangular, etc.) can be determined and/or used to provide a current density distribution that works with a given shape and size of an ECL. It will be appreciated that, in some situations, the first electrical contact 326 may have a different shape than the second electrical contact 328 without departing from the scope of the present disclosure. Additionally and/or alternatively, the electrical contacts may have an annular, hollow, or other irregular shape instead of a solid cross-sectional contact area.

FIGS. 7A-7B provide another example of a technique for promoting a uniform current density across the working surface (e.g., the side facing the curing layer) of an ECL. In particular, FIGS. 7A-7B show the front (e.g., working) and back (e.g., contact) sides 1320A, 1320B of an alternative carrier that includes multiple electrically isolated current paths defined by gaps (or “breaks”) 1325, 1329 etched away from an ECL 1322 in addition to a primary electrically isolating gap 1330 on the back side. The gaps 1325, 1329 can be shaped and arranged to promote a uniform heat distribution across a working surface 1324 of the ECL carrier (e.g., cither by promoting a uniform current density or by introducing biased current density profiles to compensate for expected losses in particular regions). Additionally and/or alternatively, the ECL 1322 can be selectively installed or applied in another manner that results in discontinuities that are consistent with the gaps 1325, 1329 shown in FIGS. 7A and 7B. As shown in FIG. 7A, the gaps 1325 formed on the front side 1320A are substantially linear and parallel, defining several elongate circuit paths that extend generally in a common direction (e.g., left to right) across the circular profile of the ECL carrier. As shown in FIG. 7B, the gaps 1329 are arranged to extend radially outward from first interconnect 1326 and second interconnect 1328. The dimensions (e.g., width, thickness) of the non-etched portions of the ECL can be adjusted to promote uniform surface heating across each discrete portion of the ECL that defines a respective circuit path. It will be appreciated that, in general, a respective width of each portion of the ECL that defines a respective circuit path is less than a respective thickness of the same portion to promote effective heat transfer. In accordance with this configuration, each pulsed current is distributed in parallel across the elongate sections along working surface 1324. In the example shown in FIGS. 7A-7B, five (broadly, at least five) isolated electrical current paths extend from each carrier electrical contact to the ECL (e.g., at a peripheral edge of the carrier body) on the rear side 1320B of the carrier. Other numbers of current pathways (e.g., one, at least two, at least three, at least four, at least six, or more) from an electrical contact disposed on the ECL may be used without departing from the scope of the present disclosure. The numbers of current pathways for each electrical contact may be the same or different. Moreover, other types of current pathways may be provided between the carrier electrical contacts and the working surface of the ECL without departing from the scope of the present disclosure. It will be appreciated that the current pathways on each side 1320A, 1320B are operatively connected (e.g., electrically coupled) in a manner that allows electrical currents to be directed through the ECL.

Referring still to the example shown in FIGS. 7A-7B, the isolated portions of the ECL 1322 on the front side 1320A define multiple resistive heating current passages (e.g., electric resistance heaters) for heating the adhesive to debond the device substrate from the carrier. As generally discussed above in connection with FIGS. 5A-5B, each resistive heating current passage can be operatively connected to electrical contact interconnects (e.g., the interconnects 336, 338) via one or more circuit pathways defined in the ECL 1322. In the example shown in FIGS. 7A-7B, fifteen discrete resistive heating circuit pathways extend across the working surface 1324 of ECL 1322, generally in a direction that is crosswise relative to a primary direction of the gap 1330. Other numbers of resistive heating circuit pathways (e.g., one, at least two, at least three, at least four, at least five, at least six, at least seven, at least eight, etc.) can be used and respectively shaped and sized without departing from the scope of the present disclosure. Each resistive heating circuit pathway is defined by an electrically isolated channel in the ECL 1322 having a length extending across the carrier along which the current travels. The channels defining each resistive heating circuit pathway each have a width transverse to the length extending across the working surface 1324. In the current example, the respective widths of the channels (e.g., a first width, a second width, a third width, etc.) decrease from a middle passage, passing through the center of the ECL 1322, to outer passages on opposite sides away from the middle passage. The passages of comparatively shorter lengths also have a lesser width compared to the passages of greater length. In other embodiments, the circuit pathways may change in width along their lengths instead of being constant along their length (e.g., the gaps 1325 may be curvilinear or disposed at irregular angles). Significantly, the configuration of the resistive heating circuit pathways can be controlled such that relatively uniform resistive heating is provided across the ECL carrier by passage of current through the passages. Other configurations can be used without departing from the scope of the present disclosure.

It will be appreciated that the surface etching techniques described above may be used independently of or in addition to controlling the electrical contact geometry as discussed above in connection with FIGS. 6A-6B.

Further, it will be appreciated that an ECL does not necessarily need a constant sheet resistance, or thickness, across its entire surface area. For example, the thickness of the ECL across the bottom (e.g., support-facing) side can be thicker than a respective thickness across the curing layer side to reduce resistive losses. In some cases, a uniform current distribution may not be desirable. For example, in some cases, a higher current density may be desired at the perimeter of the carrier. In cases when a non-uniform current density is desirable, a combination of electrical breaks or/and spatially varying resistance of the ECL (e.g., varying width and/or thickness) can be adjusted to achieve a desired current density profile at particular regions across the surface.

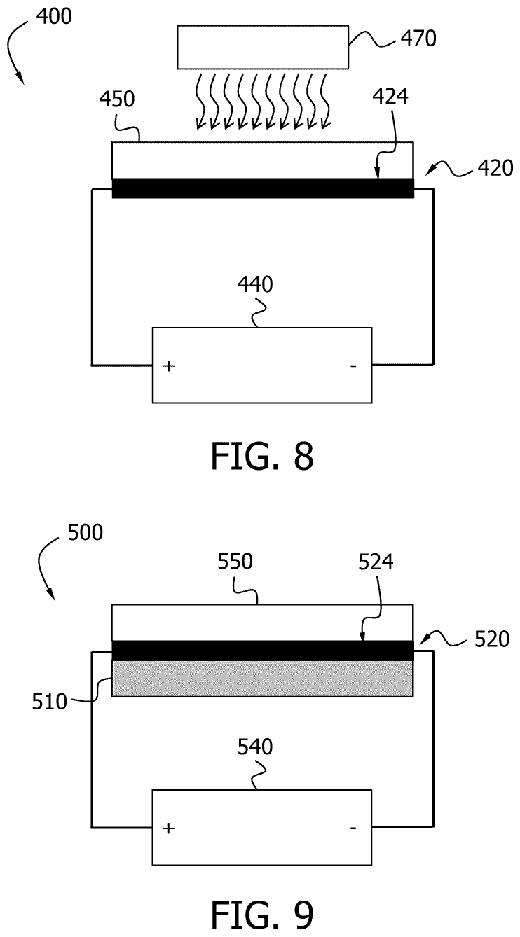

Referring back to the process 100 described in connection with FIG. 3, it will be appreciated that, after being heated by a current pulsed through the ECL 22, the curing layer 50 can also be more cooled at an accelerated rate by using heat dissipation elements. For example, the current source can be pulsed one or more times while the stack is continuously cooled. The cooling may be accomplished by convection (as shown schematically in FIG. 8) and/or conduction (as shown schematically in FIG. 9) and may be provided on the surface of the ECL surface opposite the curing layer, on the surface of the curing layer opposite the ECL, or both. Of course, heat dissipation elements can also be used to manage temperatures in the process 200 described in connection with FIG. 4.

Now referring to FIG. 8, an example of a resistive electronics structure processing system is shown schematically as reference number 400. The system 400 includes an ECL carrier 420 that is operatively coupled to a current source 440 in accordance with the examples described above. A layer 450 of curing material is deposited on (broadly, carried on) a working surface 424 of the ECL carrier 420 (thereby defining a carrier stack). The system 400 additionally includes a convective heat dissipation element 470 that faces the layer 450 to provide cooling to the carrier stack. In this example, convection provided by the heat dissipation element 470 may be supplied by an air knife, an air jet, a fan, or any compressed gas source, as non-limiting examples. Convective cooling may additionally or alternatively be applied to the ECL side of the stack without departing from the scope of the present disclosure.

Now referring to FIG. 9, another example of a resistive electronics structure processing system is shown schematically as reference number 500. The system 500 includes an ECL carrier 520 that supported by a support 510 (e.g., a platform or stage). The ECL carrier 520 is operatively coupled to a current source 540 in accordance with the examples described above. A layer 550 of curing material is deposited on (broadly, carried by) a working surface 524 of the ECL carrier 520 (thereby defining a carrier stack). In this example, the support 510 is a temperature-controlled stage or chuck (broadly, a “thermal stage”) that is in thermal contact with the ECL carrier 520 such that heat can be transferred away from the carrier stack. It will be appreciated that the thermal conductivity in the support 510 may be greater than a thermal conductivity of the curing layer 550, such that heat from the carrier stack tends to dissipate into the support 510 over time. Because the thermal mass of the support 510 is significantly greater than the carrier stack, the thermal mass of the support is adequate to rapidly cool the stack through multiple (e.g., many) thermal cycles. It will be appreciated that the support 510 does not need to be temperature-controlled to thermally process multiple layers or sub-layers, but if too many subsequent pulses are generated, the bulk of the support 510 can heat up, which can reduce the effectiveness of the support if multiple pulse cycles are performed in short succession without further active or passive cooling. Accordingly, when the support 510 is temperature-controlled, the additional temperature control can contribute to the efficiency and reliability of cooling the stack. If the support 510 is furthermore made of a thermally conductive material, such as aluminum, then it may cool the stack even more effectively.

In the examples described above in connection with FIG. 9, it will be appreciated that the thermally conductive support 510 is in thermal contact with the ECL 520. The support 510 regulates the extent to which thermal energy enters the curing layer 550 as current is pulsed through the ECL carrier 520 and additionally facilitates heat transfer away from the curing layer between the current pulses. As indicated above, the rapid pulsing and constant cooling results in the localized curing of sub-layers in sequence from the ECL-facing side of the curing layer to the free surface side.

As indicated above, dielectric materials may be used in conjunction with the ECL carriers to provide electrical insulation at sensitive locations (e.g., where a conductive or semiconductive material is provided on a main body of a support structure or is carried on a carrier). For example, as shown in FIG. 10, an example of a resistive electronics structure processing system with a dielectric layer between a support structure and an ECL carrier is shown schematically as reference number 600. In particular, the system 600 includes a chuck 610 (broadly, support such as a platform or a stage) configured to support an ECL carrier 620 carrying an electronics structure 650. A dielectric layer 670 (e.g., a thin dielectric substrate like glass) is located between chuck 610 and the ECL carrier 620 so that, when the ECL carrier is operatively connected to a current source 640 of the system 600, the chuck 610 is not exposed to the electrical current passed through the ECL carrier. It is contemplated that the dielectric layer 670 can be thermally conductive so that the above-described heat dissipation functions can be accomplished. The dielectric layer 670 can be bonded to the chuck 610 or, alternatively, can function as a carrier body for the ECL carrier 620, e.g., to provide support for the ECL and component 650.

Now referring to FIG. 11, an example of a modified version of the ECL carrier 320 with an additional dielectric layer is shown schematically in connection with the reference number 320′. The ECL carrier 320′ includes carrier body 321′ and a dielectric layer 323′ deposited on (broadly, carried by) the carrier body on one surface (broadly, at least one surface). An ECL 322′ is deposited over carrier body 321′ and dielectric layer 323′ generally in accordance with the example described above in connection with FIGS. 5A-5B. However, in the modified ECL carrier 320′, the dielectric layer provides additional thermal and/or electrical insulation between the ECL 322′ and the carrier body 321′ along one or more circuit paths where significant heat is generated. For example, the dielectric layer 323′ can retard heat propagation into the carrier body 321′ when a thermal conductivity of the dielectric layer 323′ is less than a thermal conductivity of the carrier body 321′.

Still referring to FIG. 11, when the carrier body 321′ comprises a thermally conductive material such as silicon, much of the heat from resistive heating of the ECL 322′ can be conducted into the carrier body during and after the pulsing of an electrical current. In the context of debonding (e.g., weakening an adhesive 350′ used to temporarily bond electronics structure 355′ to the ECL carrier 320′), in which a very high temperature must be reached, this means that a large current and/or a long pulse length is needed to heat the ECL 322′ to a high enough temperature to weaken an adhesive. The magnitude of current or/and the pulse length that would need to be conducted through the circuit pathway/pathways to debond the bonded electronics structure can be reduced substantially by mitigating heat losses into the carrier body 321′ along the ECL 322′ directly opposite the working surface 324′. This kind of targeted insulation can be accomplished, for example, by applying a dielectric layer 323′ (or a “carrier dielectric layer”) between the portion of the ECL 322′ that defines the working surface 324′ and the portion of the carrier body 321′ located directly beneath this portion of the ECL. When the dielectric layer 323′ is present, the current pulse through the ECL carrier 320′ is more readily capable of heating up the ECL and releasing the adhesive during debonding. Stated another way, the carrier insulating layer reduces the overall thermal diffusion of the heat generated from the resistive heating of the ECL into the carrier wafer. The effect of the carrier insulating layer means that the device substrate can be debonded more easily and with less total resistive heating energy than without the insulating layer.

For example, if the carrier body 321′ is 800 microns thick and composed of silicon and the dielectric layer 323′ is 10 microns thick and composed of SiO₂, the temperature at which the ECL heats up from a 100-microsecond-long pulse of current through the ECL is within 10% of the temperature reached if the carrier were composed of SiO₂. This is substantial because the thermal conductivity of silicon is about 100 times greater than that of SiO₂ or glass, e.g. approximately 140 W/m-K, versus about 1.2 W/m-K.

It will be appreciated that the insulating layer 323′ can be placed, shaped, and/or dimensioned non-uniformly on the carrier body 321′. For example, in regions where significant heating is not desired, the carrier dielectric layer 323′ may be thinner to permit relatively greater heat dissipation into the carrier body 321′. In regions where accumulation of heat from the resistive heating of the ECL is desired, the carrier dielectric layer may be thicker to prevent heat dissipation into the carrier.

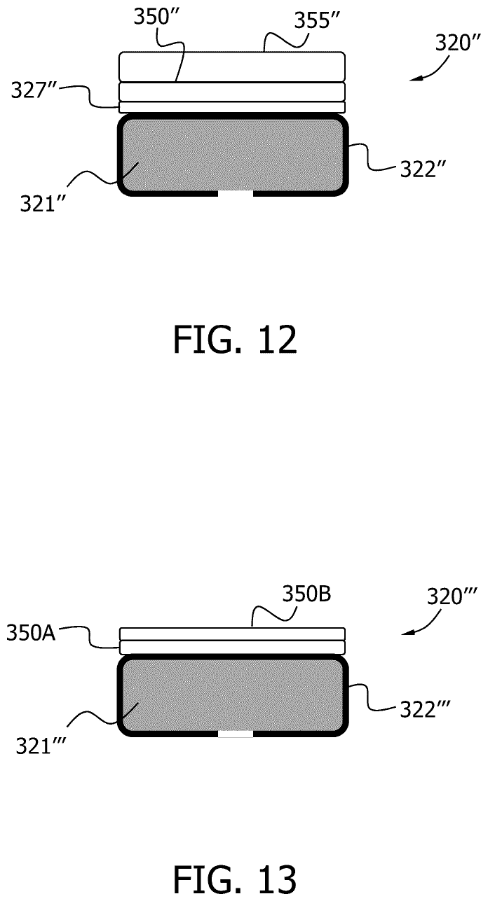

Now with reference to FIG. 12, another example of a modified version of the ECL carrier 320 with an additional dielectric layer is shown schematically in connection with the reference number 320″. Here, the ECL carrier 320″ includes carrier body 321″ coated by an ECL 322″. The ECL carrier 320″ includes a dielectric layer 327″ (or an “ECL dielectric layer”) located between the ECL 322″ and an adhesive 350″ used to carry an electronics structure 355″ on the ECL carrier. The positioning of dielectric layer 327″ promotes electrical isolation between the electronics structure 355″ and/or adhesive 350″ (e.g., if the adhesive comprises one or more electrically conductive materials).

Still referring to FIG. 12, in a further variant, the dielectric layer 327″ can act as an insulating layer and as an inorganic adhesive to create a bond between and electrical isolation between an electronics structure (e.g., electronics structure 355″) and the ECL carrier 320″. In such a case, the dielectric layer 327″ adheres to the electronics structure 355″ and the ECL 322″ to bond the device substrate to the carrier such that a different adhesive layer (e.g., layer 350″) is not needed. Heat generated by the ECL breaks down the adhesive dielectric layer during debond creating an air gap or separation for debonding. In this situation, it is contemplated that the dielectric layer 327″, like most adhesives, would not be reusable, though a remainder of the ECL carrier 320″ may be reusable. Thus, as an example, for successive cycles of bonding/debonding, multiple new dielectric layers 327″ would be deposited on (broadly, carried by) ECL 322″, but the overall carrier 320″ could be reused several times. In this example, the dielectric layer 327″ may comprise an inorganic adhesive and/or other suitable adhesive materials.

Referring now to FIG. 13, in a variation of the process described above in connection with FIG. 3, the carrier 320 can be used to cure two or more discrete layers of a common material or different curing materials (e.g., for fabricating a film having layers with different properties). An example of a modified version of the ECL carrier 320 is shown schematically in FIG. 13 using the reference number 320″. The ECL carrier 320″ includes a carrier body 321″ and an ECL 322′″ deposited on the carrier body. The ECL carrier 320″ carries a first curing layer 350A and a second curing layer 350B. It is contemplated that the first curing layer 350A can be formed following the steps of the method described above in connection with FIG. 3. Subsequent to a first stage of curing the first layer 350A, the second curing layer 350B can be cured by depositing a thermosetting polymer precursor material over the first curing layer 350A (e.g., after the above curing is complete) and repeating the steps of the method. Alternatively, the thermosetting polymer precursor materials for both layers 350A, 350B may be coated on the ECL carrier prior to any use of the current source. Then, the current source can provide current pulses to cure both of the layers 350A, 350B in succession. In either of the above situations, it will be appreciated that the current source can be configured to heat the ECL 322″ to different peak temperatures and to regulate the duration and period of the pulses based on the characteristics and temperature tolerances of each curing material.

It will be appreciated that the carriers and systems described herein can be used for a variety of different processing purposes, including for bonding a portion of an electronics structure (e.g., a device substrate) to the ECL carrier with an adhesive. For example, it will be appreciated the system 500 discussed above in connection with FIGS. 5A-5B could be adapted for adhesive bonding processes. One example of such a process may be referred to as thermocompression bonding, in which both heat and pressure are provided to facilitate bonding. With reference now to FIG. 14, an example of a resistive electronics structure processing system is shown schematically as reference number 700. The system 700 comprises a support 710 (e.g., a platform or a stage), an ECL carrier 720, and a current source 740 and other corresponding circuitry that is substantially the same as corresponding features of the system 500 described previously. The ECL carrier 720 carries an adhesive layer 750 and an electronics structure 760 to define the carrier stack. Additionally, the system 700 includes a holder 780 (e.g., a press or clamp (including a clamp arm or jaw)) that is used to apply compressive force to the carrier stack (e.g., the materials between the holder 780 and the support 710). A constant or otherwise calculated sequence of current pulses may be passed through the ECL of the carrier to heat the adhesive layer 750 while the stack is under compression to bond the stack. Then current is passed through the ECL to generate heat at an interface between the adhesive 750 and the electronics structure 760, and between the ECL carrier 720 and the adhesive 750, thereby causing the adhesive to establish a bond between the electronics device and the ECL carrier. The electronics structure 760, while bonded to the ECL carrier 720, may be processed, after which the device substrate may be debonded using the same system 700.

After the device substrate has been adhered to the carrier and has been processed, the system 700 can be used as a resistance debonder by generating heat (e.g., via the current source 740) and pressure (e.g., via the holder 780). As an example, the holder 780 can be used to apply a uniform compressive force to the carrier stack (e.g., a downward force onto the carrier stack, which is supported by a normal force of the support 710 from a generally opposite direction) between the holder 780 and the support 710. In contrast to the thermocompression bonding, where the additional pressure contributes to the strength and effectiveness of the bond, a core purpose of the compressive force in the context of debonding is to provide enough pressure to prevent arcing where the electrical contacts of the ECL carrier contact the electrical contact interconnects located on the support 710. While a downward force is shown in FIG. 14, it will be appreciated that the applied force can be exerted from the above or below the ECL carrier stack without departing from the scope of the present disclosure. While the compressive force is applied, current is also applied to the ECL (e.g., pulsed current from the pulsed current source), and the current travels through the ECL to heat the ECL and facilitate the debonding of the electronics structure from the carrier. When current is discharged from the current source, the current travels around the carrier forming a low inductance path to resistively heat the ECL. The heat is conducted to the adhesive, and heating releases the adhesive bond between the carrier and the device substrate. The ECL on the side of the carrier opposite the adhesive may be configured to have less electrical resistance than (e.g., be thicker than) the ECL on the adhesive-facing side, where the resistive heating is desired.

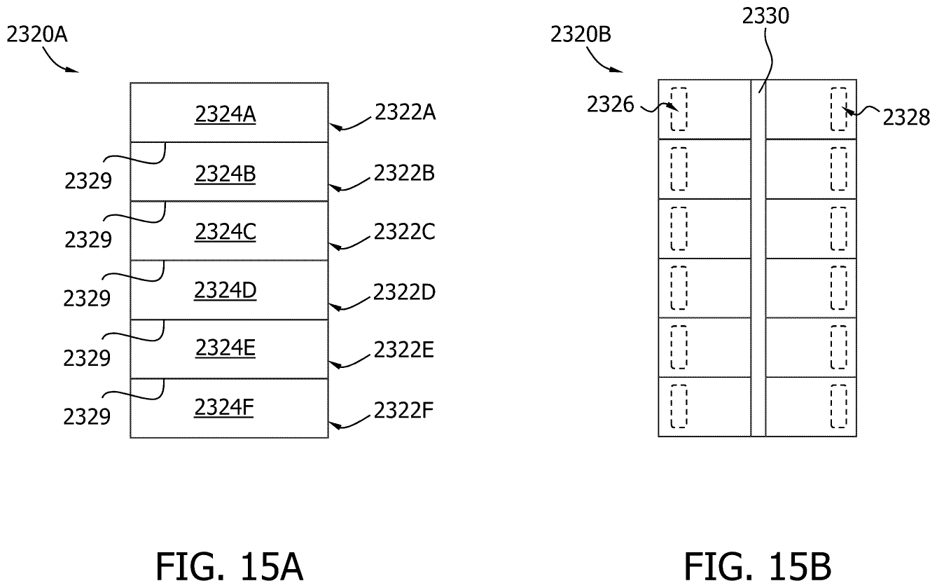

In the examples described above, the carrier stacks are generally configured so an entire ECL carrier can be processed at the same time (e.g., simultaneously). However, simultaneous processing can become complicated when the area of the working surface is large. For example, when a comparatively large, rectangular ECL carrier is used to process an electronics structure, a suitable pulsed current source supply would need to be proportionally larger, which can make the system more cumbersome and/or expensive to operate. It follows that, instead of providing a massive current to be sent across an entire large-scale ECL carrier (or panel), the carrier wafer may be split into distinct (e.g., isolated or independent) circuit paths which are able to be heated individually in separate processing actions using one or more current sources. It will be appreciated that electrical breaks may be formed in the ECL to allow for selective processing of designated subsections of a larger carrier. FIGS. 15A-15B illustrate one example of a rectangular multi-section ECL carrier 2320 with physical breaks 2329 that facilitate sequential processing over a plurality of (e.g., six, or more broadly two or more) designated ECL subsections. In particular, FIG. 15A shows a front side (working side) 2320A of the ECL carrier configured to provide a plurality of working surface portions 2324A-2324F corresponding to respective ECL subsections 2322A-2322F. FIG. 15B shows a rear side (contact side) 2320B which includes a pair of first and second electrical contacts 2326, 2328 located at each respective ECL subsection 2322A-2322F, with each set of contacts being electrically isolated from the others (e.g., a first pair from a second pair, the first pair from a third pair, etc.). A primary electrical break 2330 extends transverse to the ECL subsections 2322A-2322F, and the breaks 2329 generally extend crosswise to the primary break 2330. The breaks define a respective current passage across each working surface portions 2324A-2324F (e.g., between respective pairs of electrical contacts 2326, 2328).

Referring again to the discussion in connection with FIGS. 7A-7B above regarding controlling the shape and size of electrical contacts to adjust current density distributions, it will be appreciated that altering the geometry of some or all of the electrical contacts 2326, 2328 can be used in addition to or instead of electrical breaks between ECL subsections 2322A-2322F. Furthermore, it will be appreciated that the very short duration of pulses from the pulsed power source can effectively create a single circuit pathway between only the two contacts 2326, 2328 that are located in the designated region. This results in current paths that are effectively defined by the bounds of the physical breaks 2329 discussed above even when no linear physical breaks are present in the ECL (excluding a central electrical break separating the contact pads on the rear side 2320B). This routing of current is possible because other current paths through the ECL (e.g., to electrical contacts farther away) are not inductively favorable and thus do not constitute a path of least resistance over the short pulse time.

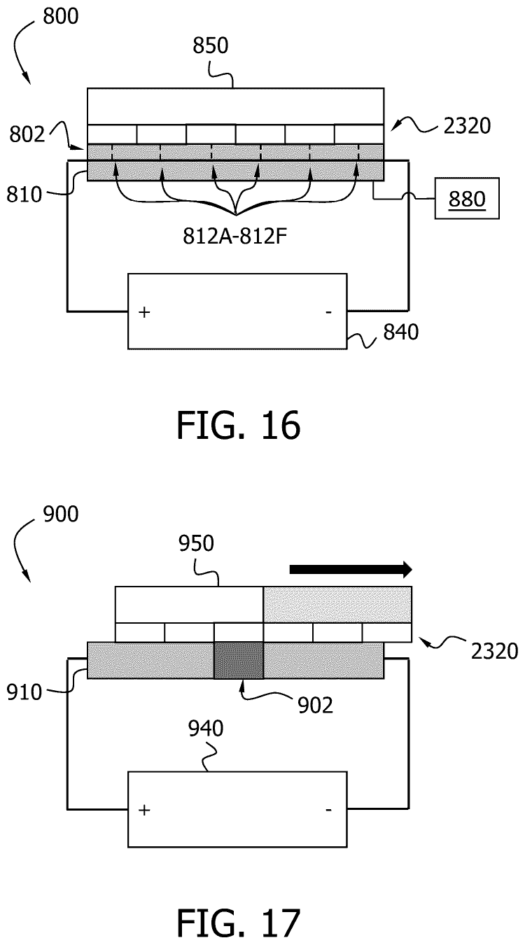

Now referring to FIGS. 16-17, two examples of resistive electronics structure processing systems that are adapted for holding and sequentially activating the rectangular multi-section ECL carrier 2320 (and/or other similarly configured ECL carriers). FIG. 16 schematically shows a system 800 in which the ECL carrier 2320 is supported by a support 810 (e.g., a platform or a stage) configured to carry the ECL carrier at a holding location 802 where each pair of electrical contacts 2326, 2328 (e.g., contact pads corresponding to each of the ECL subsections 2322A-2322F) is operatively coupled to a current source 840. The support 810 can be a vacuum chuck configured to retain the ECL carrier 2320 in electrical contact with circuitry connected to the current source 840. The support 810 includes six (broadly, a plurality of) interconnects 812A-812F configured to connect simultaneously to corresponding pairs of electrical contacts 2326, 2328 of each ECL subsection 2322A-2322F (more broadly, a plurality of pairs of electrical contacts). The support 810 and/or the current source 840 is operatively coupled to a switch 880 that is configured to direct electrical currents generated by the current source toward individual ECL subsections (e.g., any of the subsections 2322A-2322F) to allow individual portions of an electronics device 850 carried on the ECL carrier 2320 to be processed separately. In this manner, the FIG. 17 schematically shows a system 900 in which the ECL carrier 2320 is supported by a support 910 (e.g., a platform or a stage) that is configured to move the ECL carrier relative to a compact holding location 902 where an individual subsection of the ECL (e.g., any of the subsets 2322A-2322F; more broadly, a portion of the ECL carrier) can be held and a corresponding pair of electrical contacts 2326, 2328 can operatively coupled to a current source 940. The support 910 can be a vacuum chuck with characteristics consistent with other examples discussed herein. Additionally, either the support 910 or an external movement mechanism (e.g., an arm, a conveyor, any other structure capable of moving carriers horizontally along a support surface) is configured to move the ECL carrier 2320 horizontally relative to the holding location 902 so that different portions of the ECL carrier can be processed in sequence. In this manner, the rectangular ECL carrier 2320 can be conveyed one or more times to align successive portions of the ECL carrier with the vacuum and/or electrical contact portions of the support 910 so that an entire electronics structure 950 carried by the ECL carrier can be processed in a piecewise sequence. After the ECL carrier 2320 is properly aligned in the holding location 902, a vacuum component in the support 910 can be turned on to provide sufficient force to establish a robust electrical connection with the current source 940. Then, the current source 940 can provide one or more electrical current pulses to process a corresponding portion of the electronics structure 950 that is carried by the subsection of the ECL carrier 2320 receiving the electrical current from the current source. After processing is complete for the subsection, the vacuum can be released, and the rectangular carrier wafer can then be indexed relative to the carrier 910 so that a subsequent (e.g., next or adjacent) subsection of the ECL carrier 2320 can be processed. This sequence can be repeated for each of the subsections 2320A-2320F until the entire rectangular carrier is processed, or individual subsections can be selectively processed in accordance with the methods generally discussed above.

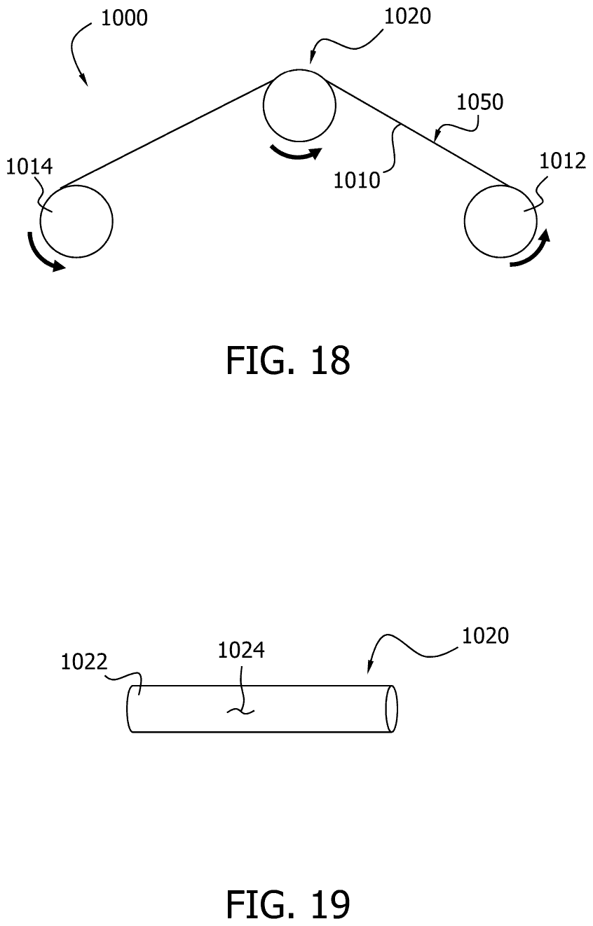

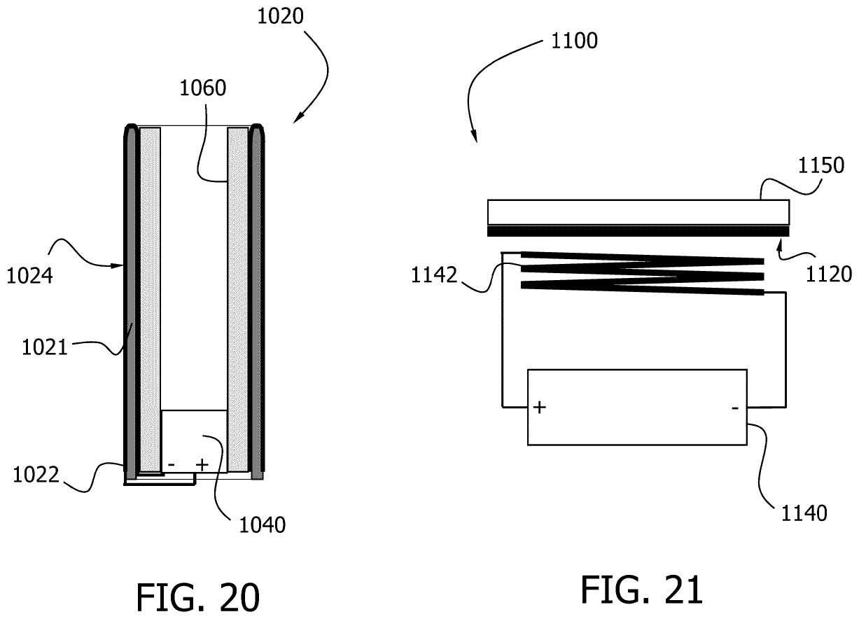

It will be appreciated that several forms of thermal processing for electronics structures (e.g., curing) can be achieved using reel-to-reel conveyor equipment with the assistance of electroconductive rollers that function as carriers for electronics structures like films. For example, FIGS. 18-20 provide a schematic overview of a resistive electronics structure processing roller system, which is shown generally as reference number 1000. As best seen in FIG. 18, the system 1000 includes a conveyable web 1010 (broadly, a moving support) that is coated with a curing material 1050. The web 1010 is supported (e.g., carried in suspension) by an unspooler 1012, a spooler 1014, and an ECL roller 1020 located between the unspooler and the spooler. It will be appreciated that the web 1010 is generally fed from the unspooler 1012 to the spooler 1014. In this example, it will be appreciated that the curing layer 1050 is deposited on (broadly, carried by) the web 1010 and is thermally processed while the web engages (broadly, is carried by) the ECL roller 1020. As best shown in FIGS. 19 and 20, the ECL roller 1020 is cylindrical and includes an ECL 1022 that defines a working surface 1024 on the cylindrical exterior of the ECL roller. As is shown in the cross section of FIG. 20, the ECL roller 1020 includes a tubular, dielectric carrier body 1021 that carries an ECL 1022 that extends continuously across the outer and inner perimeters of the carrier body 1021. The ECL roller 1020 can further be carried on a cylindrical support 1060 which functions as a thermal stage through which heat is dissipated. The ECL roller 1020 is operatively (e.g., electrically) coupled to a current source 1040 so that a current can travel across the outer and inner portions of the ECL 1022 in a low-inductance electrical loop. It is contemplated that a variety of operative electrical connectors such as slip rings (not shown) can be used to establish an electrical connection to the pulsed power supply and/or to supply fluid to the temperature-controlled stage.

Referring now to FIG. 21, as an alternative to directly connecting a pulsed current source electrically across an ECL. A current source may be connected to an inductive element that is placed near the ECL. A system showing this configuration is shown generally as reference number 1100. The system 1100 includes an ECL carrier 1120 that carries an electronics structure 1150 and a pulsed current source 1140 that provides a circuit including an inductive element 1142 (e.g., a heating inductor). It is contemplated that the inductive element 1142 can be located in a support structure (e.g., inside a stage). The ECL carrier 1120 is positioned (e.g., supported) relative to the inductive element 1142 to induce eddy currents in the ECL to generate heat when the current from the pulsed current source 1140 is discharged across the inductive element. An advantage of this approach is that no direct physical/electrical contact is needed to the ECL from the pulsed current source. The inductive element 1142 may also be placed on either side of the ECL. However, if there are electrically sensitive layers on one side of the ECL, the heating inductor should be placed on a side of the ECL opposite the electrically sensitive layers. Inductive elements can be used for various kinds of thermal processing, including curing a film, heating an adhesive to bond an electronics structure substrate to a carrier, heating an adhesive to debond an electronics structure substrate from a carrier, or to print functional material from a carrier to a donor substrate. One example of a pulsed power source is a capacitor bank that is discharged across the heating inductor. Another example of a pulsed power source is a high-power microwave source that is modulated across the heating inductor.

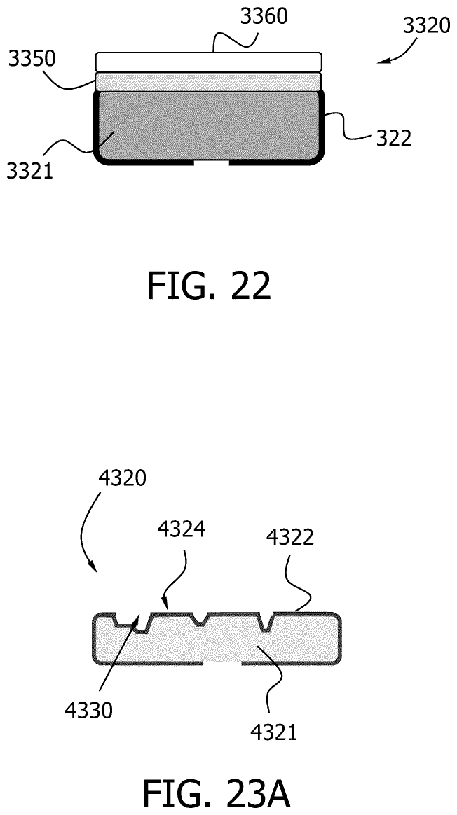

In another example, an electrically conductive adhesive (e.g., an electrically conductive adhesive layer or “ECAL”) may be used with an ECL carrier such that passage of current through the electrically conductive adhesive causes resistance heating of the adhesive and thus debonding. With reference now to FIG. 22, an example of an ECL carrier 3320 configured to temporarily carry an electronics structure 3360 with an ECAL 3350 is shown. The ECL carrier 3320 includes a reusable carrier body 3321 and a reusable ECL 3322 which provides at least one electrical interface to electrically connect a current source to the ECAL 3350 to provide a circuit path through which an electrical current can travel. It is contemplated that the ECAL 3350 is nonresuable and may be used in conjunction with the reusable ECL 3322 or any other permanent or reusable current pathway carried by the carrier for passage of current from the carrier supply electrical contact to the ECAL. As shown in FIG. 22, the reusable ECL 3322 does not cover the working side of the carrier body 3321 but extends around the edges of the carrier body to be operatively connected to the ECAL to facilitate the passage of a current to the ECAL. It will be appreciated that the reusable ECL layer 3322 can cover the working side of the carrier (e.g., entirely underlie the ECAL 3350 and/or extend between the ECAL and the carrier body 3321) without departing from the scope of the present disclosure. The ECAL 3350 is formed by depositing an electrically conductive adhesive to make electrical (ohmic) contact with at least a portion of the ECL 3322. This forms a hybrid ECL. In this embodiment, electric current (e.g., pulsed electric current) is passed from a current source to make direct electrical (ohmic) contact with the ECL carrier 3320 and indirect contact with the ECAL 3350 that is also connected to the ECL 3322. The current travels through the ECAL 3350 to resistively heat the electrically conductive adhesive weaken a bond between the ECAL and the electronics structure 3360. After separation of the electronics structure and the carrier, a remainder of the ECAL 3350 may be cleaned from the device substrate and/or carrier, and the ECL carrier 3320 can be reused in subsequent bond/debond cycles by depositing a new ECAL to be in electrical contact with the ECL 3322, followed by bonding of a subsequent electronics structure to the newly applied ECAL for processing of the subsequent device substrate.

In cases when electrical isolation is desired between the ECAL and the electronics substrate, a dielectric layer may be deposited on the ECAL (e.g., to be located between the ECAL and device substrate) as generally described in connection with FIG. 12. For example, the ECL dielectric layer may be an electrically insulating adhesive and may be placed between the non-reusable ECL and the device substrate.

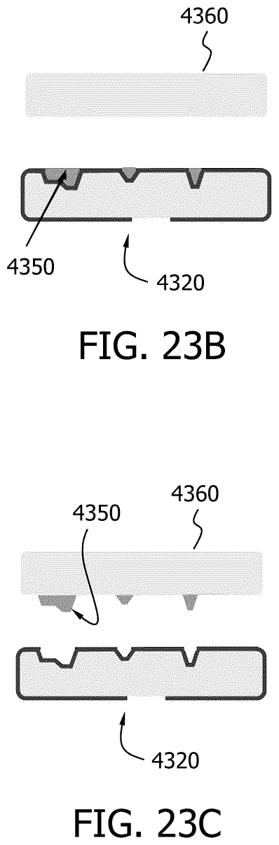

Although the types of processing described herein focus on electronics structures carried by ECL carriers, it is possible to adapt the connective features of the ECL carriers described herein for use in the printing of functional materials. FIGS. 23A-23C schematically show another example of an ECL carrier 4320 adapted for carrying and subsequently releasing (e.g., printing) a functional material (e.g., inks, pastes, etc.) on a donor substrate such as an electronics structure. As shown in FIG. 23A, the ECL carrier 4320 includes a carrier body 4321 that has a plurality of wells 4330 (broadly, at least one well) formed in the carrier body on a working side. An ECL 4322 is applied on (or carried by) the carrier. The ECL 4322 generally conforms to the shapes of the wells to define a working surface 4324 that conforms to the shape of the wells 4330. As is further shown in FIG. 23B, a functional material 4350 to be printed on a donor substrate 4360 can be temporarily carried (e.g., packed, deposited) in one or more of the wells 4330. Then, the ECL carrier 4330 can be secured in a holding location on a vacuum chuck or other a related structure described above which provides an electrical interface for the ECL carrier 4320 to generate heat at an interface between the ECL 4322 and the functional material 4350. As best shown in FIG. 23C, when the functional material has been sufficiently heated by one or more pulses from a connected current source, the functional material releases from the working surface 4324 of the ECL carrier 4320 and attaches to a receiving surface of the donor substrate 4360.

It will be appreciated that the above embodiments are described by way of example without limitation and that aspects of one or more embodiments can be combined with aspects of other embodiments without departing from the scope of the present disclosure.

Example: Using one of the embodiments shown in FIGS. 5A-5B or in FIG. 14, a 1200 nm thick tungsten-titanium alloy (90% weight W and 10% weight Ti) is sputtered onto a 300 mm silicon carrier body wafer (the carrier body having a thickness of around 500 μm to around 1.5 mm, and preferably between around 800 μm to around 1.1 mm) to form an ECL on the first side of the wafer. The sheet resistance across the ECL is approximately 0.05 ohm/sq. The same material is sputtered at 2000 nm thick on the second side of the wafer. Some of the sputtered coating is etched away on the second side of the wafer to form an electrical break. Additionally, such as shown in FIGS. 7A-7B, some of the sputtered coating may be etched away on both sides of the carrier wafer to distribute the current from the pulsed current source over the first side of the carrier wafer. An organic adhesive layer that is 50 μm thick is then used to bond the first side of the ECL carrier to another silicon wafer (e.g., a device substrate), which defines a carrier stack. After bonding, the device wafer may thinned down to a thickness of about 20 μm. After the thinning, the carrier wafer (or working) side of the carrier stack is placed on a retainer/press chuck or vacuum chuck to secure the stack and electrically connect the stack to a pulsed current source. The pulsed current source includes five DX2-950 lamp drivers (manufactured by PulseForge, Inc., Austin, TX) connected in parallel. The pulsed current source is charged to 950 V, and is discharged at a peak current of 19,000 amps in 80 microseconds to generate heat of an intensity of approximately 2 J/cm² into the ECL to heat the ECL and release the adhesive bond between the carrier wafer and the device wafer. For example, when the ECL is heated, it can provide heat with an intensity of at least approximately 30 kW/cm² during debonding cycles (by comparison, a heating intensity as low as around 500 W/cm² is possible for drying and curing processes). The device wafer is removed from the stack, and the carrier wafer and the device wafer are cleaned. The cleaning can be done using wet processes such as solvent soak or spray or wet etch, or using dry processes such as plasma, mechanical peel-off, or dry etch. The device wafer is then transported to the next stage of processing, and the carrier wafer is reused again for another bond/debond process. Example uses are similar for other specific examples described above except, for example, where dielectric layers serve as insulators (e.g., FIGS. 11, 12), and/or where an ECAL is used (e.g., FIG. 22). For debonding, it is contemplated that Additionally, depending on the desired uses of the ECL carrier, corresponding ECLs can be formed in varying thicknesses. For example, a suitable ECL thickness may be as low as around 0.1 μm to around 5 μm, with lower thicknesses generally being possible for lower-intensity processing (e.g., curing) as opposed to higher-intensity processing (e.g., debonding).

It will be appreciated that several types of current sources can be used in connection with the above-described equipment and variations thereof. One example of a power source is a capacitive discharge disposed across the ECL. For example, the pulsed current source may comprise a capacitor bank. The capacitors in the capacitor bank may be, for example, electrolytic or pulse discharge capacitors. The capacitor bank may have a variable charging voltage and a controllable output current pulse length. That is, the current profile may be controlled and may deliver multiple pulses at high frequency. This allows the same system to accommodate different wafer sizes (e.g., diameters) as well as different sheet resistances of the ECL. The pulsed current source may have a tunable output current as well as total energy delivered. The capacitor bank may be switched with IGBT-based switches forming a driver and may be placed in parallel to deliver the needed current to the ECL. Alternatively, the capacitor bank may be switched with an SCR-based switch forming a driver. Alternatively, the pulsed current source may be inductive. The current path through the ECL may include at least one winding of a transformer (the secondary winding). An input current through a primary winding of the transformer may step up or step down the current delivered to the ECL. The pulsed current source may deliver current in an inclusive range of 100 to 30,000 amps (e.g., at least 5,000, at least 10,000, at least 15,000, at least 20,000, or at least 25,000 amps) with a pulse length in an inclusive range of 10-10,000 microseconds at a pulse frequency in an inclusive range of from 0.1 to 20,000 Hz. The current source may additional comprise a control system (or computer) that includes at least one processor (e.g., debonder controller) and one or more storage devices (e.g., non-transitory tangible storage medium) storing processor-executable instructions to perform functions described herein, such as delivering pulsed current for thermal processing operations. The processor-executable instructions embody functional aspects of the system and are selectively executable by the processor to perform functions described above. The control system may further include a user interface including a user input (e.g., keypad, buttons, or other actuators) and a display configured to indicate status of the system and other functional aspects there to a user. The control system is responsive to the user input to execute instructions stored on the tangible storage medium. The apparatus may also include equipment for the front-end module to transfer the samples to be debonded, a wafer transfer robot, and carrier or device separator and vacuum chuck. Other configurations can be used without departing from the scope of the present disclosure.

The carriers, systems, and processes described above are provided as examples of different ways to process electronics structures. It will be appreciated that the carriers and systems described herein can be used, or adapted for use, in a variety of thermal processing settings, including without limitation curing a film, heating an adhesive to bond an electronics structure substrate to a carrier, heating an adhesive to debond an electronics structure substrate from a carrier and/or printing a functional material on a donor structure.

When introducing elements of the present disclosure or the preferred embodiments(s) thereof, the articles “a”, “an”, “the” and “said” are intended to mean that there are one or more of the elements. The terms “comprising”, “including” and “having” are intended to be inclusive and mean that there may be additional elements other than the listed elements.

In view of the above, it will be seen that the several objects of the present disclosure are achieved and other advantageous results attained.

As various changes could be made in the above constructions and methods without departing from the scope of the present disclosure, it is intended that all matter contained in the above description and shown in the accompanying drawings shall be interpreted as illustrative and not in a limiting sense.

### Other Statements of the Disclosure

The following are statements or features of invention described in the present disclosure. Some or all of the following statements may not be currently presented as claims. Nevertheless, the statements are believed to be patentable and may subsequently be presented as claims. Associated methods corresponding to the statements or apparatuses below, and products and apparatuses corresponding to the methods below, are also believed to be patentable and may subsequently be presented as claims. It is understood that the following statements may refer to and be supported by one, more than one, or all the embodiments described above.
A1. A carrier for processing electronics structures comprising:
an electrically conductive layer on a working side of the carrier and defining a working area for carrying a portion of an electronics structure for processing;
a first electrical contact in electrical communication with the electrically conductive layer; and
a second electrical contact in electrical communication with the electrically conductive layer to define a circuit path in the electrically conductive layer between the first electrical contact and the second electrical contact;
wherein the electrically conductive layer is configured to generate distributed heat across the working area with an intensity that is substantially uniform across the working area to within ±10% when an electrical current is provided through the circuit path.
A2. The carrier of statement A1, wherein the electrically conductive layer defines a plurality of circuit paths arranged in parallel between the first electrical contact and the second electrical contact;
wherein the electrically conductive layer is configured to generate distributed heat across the working area that is substantially uniform across the working area when an electrical current is provided through the plurality of circuit paths.
A3. The carrier of statement A2, wherein the electrically conductive layer is divided into a plurality of electrically isolated channels disposed between the first electrical contact and the second electrical contact.
A4. The carrier of statement A3, wherein at least one of the plurality of electrically isolated channels differs in at least one of a channel width and a channel thickness relative to at least another one of the plurality of electrically isolated channels.
A5. The carrier of statement A3, wherein the electrically isolated channels are bounded by gaps in the electrically conductive layer.
A6. The carrier of statement A3, wherein the electrically isolated channels extend across the working side.
A7. The carrier of statement A1, further comprising:
a second electrically conductive layer on the working side of the carrier and defining a second working area; and
a third electrical contact in electrical communication with the second electrically conductive layer to define a second circuit path in the second electrically conductive layer between the third electrical contact and another electrical contact;
wherein the second electrically conductive layer is configured to generate distributed heat across the second working area that is substantially uniform across the second working area when an electrical current is provided through the second circuit path.
A8. The carrier of statement A1, wherein the first electrical contact is shaped and sized to engage a current source such that a substantially uniform current density is provided across all portions of the circuit path when the electrical current is provided through the circuit path.
A9. The carrier of statement A1, wherein the electrically conductive layer is carried by a carrier body, wherein the electrically conductive layer extends over an edge of the carrier body from the working side to an electrical contact side of the carrier opposite the working side, wherein the first electrical contact is located on the electrical contact side.
A10. The carrier of statement A9, wherein the second electrical contact is located on the electrical contact side.
A11. The carrier of statement A10, wherein the electrical contact side of the carrier is configured to operatively engage a current source to define a current path for the electrical current.
A12. The carrier of statement A11, wherein the electrical contact side of the carrier is further configured to operatively engage a heat dissipation element.
A13. The carrier of statement A1, wherein the electrically conductive layer has a thickness of between 0.1 μm and about 5 μm.
A14. The carrier of statement A1, wherein the electrically conductive layer has a first layer thickness at the working area and a second layer thickness outboard of the working area, the second layer thickness being greater than the first layer thickness.
A15. The carrier of statement A1, wherein the electrically conductive layer is reusable to permit reuse of the carrier.
A16. The carrier of statement A1, wherein the electrically conductive layer is carried by a carrier body, and wherein the carrier body has a thickness of approximately 500 μm to 1.5 mm.
A17. A carrier stack comprising the carrier of statement A1 and the electronics structure, the electronics structure being adhesively bonded to the working side of the carrier.
A18. The carrier stack of statement A17, wherein an adhesive that adhesively bonds the electronics structure to the working side is thermally stable up to a temperature of approximately 300° C.
A19. The carrier stack of statement A17, wherein the electrically conductive layer comprises an electrically conductive adhesive.
A20. An electronics processing system comprising the carrier stack of statement A14 and a platform, the platform comprising a retaining location configured to temporarily retain the carrier stack on the platform during processing, and wherein the platform comprises a first electrical contact interface and a second electrical contact interface operatively coupled to a current source, wherein the first electrical contact interface and the second electrical contact interface are configured to engage the first electrical contact and the second electrical contact, respectively, when the carrier stack is retained in the retaining location.
A21. The electronics processing system of statement A17, wherein the retaining location comprises a vacuum configured to temporarily retain the carrier stack on the platform.
A22. The electronics processing system of statement A17, further comprising a carrier transport, the carrier transport being configured to move the carrier stack to the retaining location such that the first electrical contact engages the first electrical contact interface and the second electrical contact engages the second electrical contact interface.
A23. The electronics processing system of statement A19, wherein the carrier comprises a plurality of first electrical contacts and second electrical contacts paired with respective first electrical contacts, and wherein the carrier transport is configured to move the carrier relative to the retaining location such that each pair of first and second electrical contacts can engage the first electrical contact interface and the second electrical contact interface.
A24. The electronics processing system of statement A17, wherein the carrier comprises a plurality of first electrical contacts and second electrical contacts paired with respective first electrical contacts, wherein the platform comprises a plurality of first electrical contact interfaces and second electrical contact interfaces paired with each respective first electrical contact interface, and wherein each pair of first and second electrical contact interfaces is configured to engage a corresponding pair of first and second electrical contacts when the carrier stack is retained in the retaining location.
A25. The electronics processing system of statement A21, wherein the current source is operatively coupled to a switch, the switch being configured to direct a pulsed current to one or more of the pairs of first and second electrical contacts.
A26. The electronics processing system of statement A17, further comprising a heat dissipator configured to dissipate heat from the carrier stack when the carrier stack is retained in the retaining location.
A27. The electronics processing system of statement A23, wherein the heat dissipator comprises a thermally conductive contact configured to engage at least a portion of the carrier when the carrier stack is retained in the retaining location.
B1. A method for thermal processing comprising:
providing a carrier stack comprising an electrically conductive carrier and an electronics structure adhesively bonded thereto,
wherein the electrically conductive carrier comprises an electrically conductive layerdefining a working area of the electrically conductive carrier, the electrically conductive layer defining a circuit path;
wherein at least a portion of the electronics structure is adhesively bonded to the carrier at the working area using an adhesive;
wherein the electrically conductive layer is configured to conduct a current through the circuit path to generate distributed heat in the working area;
processing the electronics structure while the electronics structure is adhesively bonded to the electrically conductive carrier;
connecting the electrically conductive carrier to a current source to establish a complete circuit between the current source and the circuit path;
using the current source to direct a plurality of electrical pulses through the circuit path to generate sufficient heat in the adhesive to weaken the adhesive bond between the electronics structure and the electrically conductive carrier; and
removing the electronics structure from the electrically conductive carrier when the adhesive bond is weakened.
B2. The method of statement B1, wherein each electrical pulse has an intensity sufficient to raise a local temperature of the adhesive above a destructive threshold temperature for the adhesive, and wherein each successive electrical pulse follows a prior electrical pulse by enough time to dissipate heat such that an instantaneous temperature of the electronics structure is never raised above a destructive threshold temperature for the electronics structure.
B3. The method of statement B2, wherein the destructive threshold temperature for the adhesive is above around 300° C.
B4. The method of statement B2, wherein the destructive threshold for the electronics structure is below around 300° C.
B5. The method of statement B1, wherein the electrically conductive carrier comprises a first electrical contact and a second electrical contact, the circuit path extending between the first electrical contact and the second electrical contact; and
wherein connecting the carrier to a current source comprises operatively connecting the first electrical contact and the second electrical contact to the current source to form a complete circuit including the circuit path.
B6. The method of statement B1, wherein a current density of current passed through the circuit path across a portion of the electrically conductive layer that defines the working area is evenly distributed within about ±10% over the working area.
C1. A method for thermal processing comprising:
providing a carrier stack comprising:
a carrier comprising an electrically conductive layer defining a working area of the carrier, the electrically conductive layer defining a circuit path, wherein the electrically conductive layer is configured to conduct a current through the circuit path to generate distributed heat across the working area; and
a layer of curable thermosetting polymer carried by the working area; providing;
securing the carrier in electrical contact with a current source, the current source being configured to provide pulses of current to the electrically conductive layer;
emitting a pulse of current for between 10 us and 100 ms to heat the working area to a working temperature at least 100° C. above a maximum steady-state temperature of the polymer;
after the working temperature has been reached, terminating the pulse of current to allow an average temperature at the working area to drop below the maximum steady-state temperature of the polymer;
after the average temperature at the working area has dropped below the maximum steady-state temperature of the polymer, repeating the steps of emitting a pulse and terminating a pulse until the entire layer of the polymer is cured.
C2. The method of statement C1, further comprising cooling the carrier stack with a heat dissipator while the polymer is being cured.
D1. A method for thermal processing comprising:
providing a carrier stack comprising:
a carrier comprising an electrically conductive layer defining a working area of the carrier, the electrically conductive layer defining a circuit path, wherein the electrically conductive layer is configured to conduct a current through the circuit path to generate distributed heat across the working area; and
a layer of curable thermosetting polymer carried by the working area;
securing the carrier in electrical contact with a current source, the current source being configured to provide pulses of current to the electrically conductive layer;
emitting a sequence of pulses from the current source to heat the polymer to cure the polymer in a series of sub-layers, wherein a first sub-layer to be cured is located adjacent the working area, and wherein each successive sub-layer to be cured is located farther from the working areas and is located adjacent the sub-layer most recently cured.
D2. The method of statement D1, wherein emitting the sequence of pulses comprises:
emitting a pulse of current for between 10 us and 100 ms to heat the working area to a working temperature approximately 200° C. above a maximum steady-state temperature of the polymer;
as soon as the working temperature has been reached, terminating the pulse of current to allow an average temperature at the working area to drop below the maximum steady-state temperature of the polymer; and
after the average temperature at the working area has dropped below the maximum steady-state temperature of the polymer, repeating the steps of emitting a pulse and terminating a pulse until the entire layer of the polymer is cured.
D3. The method of statement D1, further comprising cooling the carrier stack with a heat dissipator while the polymer is being cured.
E1. A carrier for temporarily carrying an electronics structure for processing, the carrier comprising:
an electrical contact side of the carrier;
a working side of the carrier opposite the electrical contact side;
an electronics structure support surface on the working side configured to support the electronics structure temporarily for processing of the electronics structure;
a first electrical contact on the electrical contact side of the carrier; and
a first resistance heating current passage on the working side of the carrier, the first resistance heating current passage being electrically coupled to the first electrical contact and being configured to generate heat via current passed through the first resistance heating current passage via the first electrical contact.
E2. A carrier as set forth in statement E1, further comprising a second electrical contact on the electrical contact side, the second electrical contact being electrically coupled to the first resistance heating current passage.
E3. A carrier as set forth in statement E1, wherein the first resistance heating current passage is configured to direct current flow along a length of the first resistance heating current passage, the first resistance heating current passage having a width transverse to the length, the width being greater than a thickness of the first resistance heating current passage.
E4. A carrier as set forth in statement E1, wherein the first resistance heating current passage is configured to create distributed heat across a width of the first resistance heating current passage, the width being greater than a thickness of the first resistance heating current passage.
E5. A carrier as set forth in statement E1, further comprising a second electrical contact on the electrical contact side and being electrically coupled to the first resistance heating current passage, wherein the first electrical contact is electrically isolated on the electrical contact side from the second electrical contact.
E6. A carrier as set forth in statement E1, further comprising a carrier body, the first resistance heating current passage being on a working side of the carrier body, and the first electrical contact being on an electrical contact side of the carrier body.
E7. A carrier as set forth in statement E6, wherein the first electrical contact is electrically coupled to the first resistance heating current passage via a first current pathway, the first current pathway extending over a peripheral edge of the carrier body for transmitting the current from the first electrical contact to the first resistance heating current passage.
E8. A carrier as set forth in statement E7, further comprising an electrically conductive layer, the electrically conductive layer defining the first resistance heating current passage, the first current pathway, and the first electrical contact.
E9. A carrier as set forth in statement E8, wherein the electrically conductive layer wraps around the peripheral edge of the carrier body.
E10. A carrier as set forth in statement E6, wherein the first electrical contact is electrically coupled to the first resistance heating current passage via a first current pathway and a second current pathway in parallel with the first current pathway.
E11. A carrier as set forth in statement E10, further comprising an electrically conductive layer on the electrical contact side of the carrier body, the electrically conductive layer defining the first and second current pathways, the first and second current pathways being electrically separated from each other by electrically isolating breaks in the electrically conductive layer.
E12. A carrier as set forth in statement E11, further comprising a second resistance heating current passage on the working side of the carrier, the second resistance heating current passage being configured to generate heat via current passed therethrough.
E13. A carrier as set forth in statement E12, wherein the second resistance heating current passage is electrically coupled to the first electrical contact.
E14. A carrier as set forth in statement E12, further comprising a third electrical contact on the electrical contact side of the carrier, the third electrical contact being electrically isolated from the first electrical contact, the second resistance heating current passage being electrically coupled to the third electrical contact.
E15. A carrier as set forth in statement E14, further comprising a fourth electrical contact on the electrical contact side of the carrier, the fourth electrical contact being electrically isolated form the first electrical contact, the second resistance heating current passage being electrically coupled to the fourth electrical contact.
E16. A carrier as set forth in statement E14, further comprising an electrically conductive layer on the working side of the carrier, the electrically conductive layer defining the first and second resistance heating current passages, the first and second resistance heating current passages being separated from each other by an electrically isolating break in the electrically conductive layer.
E17. A carrier as set forth in statement E1, further comprising a second resistance heating current passage on the working side of the carrier, the second resistance heating current passage being configured to generate heat via current passed therethrough.
E18. A carrier as set forth in statement E17, further comprising an electrically conductive layer on the working side of the carrier, the electrically conductive layer defining the first and second resistance heating current passages, the first and second resistance heating current passages being separated by a first electrically isolating break in the electrically conductive layer.
E19. A carrier as set forth in statement E18, further comprising a second electrical contact on the electrical contact side, the second electrical contact being electrically coupled to the first resistance heating current passage, the first and second electrical contacts being separated by a second electrically isolating break on the electrical contact side, the first electrically isolating break extending crosswise with respect to the second electrically isolating break.
E20. A carrier stack comprising the carrier of statement E1 in combination with the electronics structure, the electronics structure being adhesively bonded to the working side of the carrier.
E21. A carrier stack comprising the carrier of statement E1 in combination with the electronics structure, the electronics structure comprising a cured film on the working side of the carrier.
E22. A carrier as set forth in statement E1, further comprising a dielectric layer, the dielectric layer separating the first resistance heating current passage from the electronics structure support surface.
E23. A carrier as set forth in statement E1, wherein the first resistance heating current passage defines at least part of the electronics structure support surface.
E24. A carrier as set forth in statement E1, further comprising a dielectric layer, the carrier body carrying the dielectric layer, the dielectric layer being between the carrier body and the first resistance heating current passage.
F1. A carrier for temporarily carrying an electronics structure comprising:
a plurality of resistance heating current passages on a working side of the carrier, the plurality of resistance heating current passages extending across a working area of the working side, the plurality of resistance heating current passages being separated from each other by electrically isolating breaks.
F2. A carrier as set forth in statement F1, plurality of resistance heating current passages are formed by an electrically conductive layer, and the electrically isolating breaks are electrically isolating breaks in the electrically conductive layer.
F3. A carrier as set forth in statement F1, wherein the plurality of resistance heating current passages are configured to direct current along respective lengths of the resistance heating current passages.
F4. A carrier as set forth in statement F3, wherein each resistance heating current passage has a respective width that is greater than a respective thickness of the resistance heating current passage.
F5. A carrier as set forth in statement F1, wherein the plurality of resistance heating current passages comprise first, second, and third resistance heating current passages.
F6. A carrier as set forth in statement F5, wherein the first resistance heating current passage has a first width, the second resistance heating current passage has a second width different from the first width, and the third resistance heating current passage has a third width different from the second width.
F7. A carrier as set forth in statement F6, wherein the second resistance heating current passage is between the first and second resistance heating current passages.
F8. A carrier as set forth in statement F7, wherein the third resistance heating current passage is longer than the second resistance heating current passage, and the second resistance heating current passage is longer than the first resistance heating current passage.
F9. A carrier as set forth in statement F5, further comprising a first electrical contact on an electrical contact side of the carrier opposite the working side, the first electrical contact being electrically coupled to the plurality of resistance heating current passages.
F10. A carrier as set forth in statement F9, further comprising a second electrical contact on the electrical contact side of the carrier, the second electrical contact being electrically coupled to the plurality of resistance heating current passages.
F11. A carrier as set forth in statement F5, further comprising first and second electrical contacts on an electrical contact side of the carrier opposite the working side, the first resistance heating current passage being electrically coupled to the first and second electrical contacts.
F12. A carrier as set forth in statement F11, further comprising third and fourth electrical contacts on the electrical contact side of the carrier, the second resistance heating current passage being electrically coupled to the third and fourth electrical contacts.
F13. A carrier as set forth in statement F12, further comprising fifth and sixth electrical contacts on the electrical contact side of the carrier, the third resistance heating current passage being electrically coupled to the fifth and sixth electrical contacts.
F14. A carrier as set forth in statement F13, wherein the first, second, and third resistance heating current passages have respective lengths extending crosswise with respect to an electrically isolating break that isolates the first electrical contact from the second electrical contact, the third electrical contact from the fourth electrical contact, and the fifth electrical contact from the sixth electrical contact.
G1. A method of thermally processing an electronics structure, the method comprising:
securing an electrically conductive carrier to a stage with an electrical contact side of the electrically conductive carrier facing the stage to form a first electrical connection between the stage and a first electrical contact on the electrical contact side of the electrically conductive carrier and form a second electrical connection between the stage and a second electrical contact of the carrier on the electrical contact side of the electrically conductive carrier;
passing at least one pulse of current through the electrically conductive carrier from the first electrical connection to the second electrical connection to generate heat to thermally process an electronics structure temporarily carried by the electrically conductive carrier.
G2. A method as set forth in statement G1, wherein securing the electrically conductive carrier to the stage comprises securing the electrically conductive carrier with a vacuum.
G3. A method as set forth in statement G1, wherein passing at least one pulse of current through the electrically conductive carrier comprises passing a plurality of pulses of current through the electrically conductive carrier.
G4. A method as set forth in statement G1, wherein thermally processing the electronics structure comprises curing a film carried by the electrically conductive carrier.
G5. A method as set forth in statement G1, wherein thermally processing the electronics structure comprises curing an adhesive to temporarily bond an electronics structure substrate to the electrically conductive carrier.
G6. A method as set forth in statement G1, wherein thermally processing the electronics structure comprises heating an adhesive to loosen the adhesive to permit removal of an electronics structure substrate from the electrically conductive carrier.
G7. A method as set forth in statement G1, wherein passing at least one pulse of current through the electrically conductive carrier comprises creating distributed heat across a working area of the electrically conductive carrier to substantially uniformly thermally process the electronics structure.
G8. A method as set forth in statement G7, wherein passing at least one pulse of current through the electrically conductive carrier comprises passing current through a plurality of resistance heating current passages on a working side of the electrically conductive carrier opposite the electrical contact side.
H1. A system for thermally processing an electronics structure supported by an electrically conductive carrier, the system comprising:
a stage for supporting the electrically conductive carrier, the stage including a retaining location configured to secure the electrically conductive carrier to the stage, the stage including first and second electrical contact interfaces configured to form respective electrical connections with the electrically conductive carrier when the electrically conductive carrier is secured to the stage; and
a power supply configured to be connected in circuit with the electrically conductive carrier via the first and second electrical contact interfaces and configured to deliver at least one pulse of current to the first electrical contact interface for passing the current through the electrically conductive carrier.
H2. A system as set forth in statement H1, wherein the power supply includes a switch configured to transmit sequential pulses of current to the first electrical contact interface.
H3. A system as set forth in statement H2, wherein the power supply includes a capacitor.
H4. A system as set forth in statement H2, wherein the power supply includes a capacitor bank.
H5. A system as set forth in statement H1, wherein the retaining location comprises a vacuum configured to secure the electrically conductive carrier to the stage.
H6. A system as set forth in statement H1, wherein the stage comprises a support surface configured to support the electrically conductive carrier, the first and second electrical contact interfaces at least partially defining the support surface.
H7. A system as set forth in statement H1, wherein the stage further comprises second and third electrical contact interfaces configured to form respective electrical connections with the electrically conductive carrier when the electrically conductive carrier is secured to the stage.
H8. A system as set forth in statement H1, in combination with the electrically conductive carrier.
J1. A method of thermally processing an electronics structure, the method comprising:
heating a roller by passing at least one pulse of current through a resistance heating current passage of the roller; and
thermally processing the electronics structure by moving the electronics structure across the roller to receive heat from the roller.
J2. A method as set forth in statement J1, wherein heating the roller comprises passing a sequence of pulses of current through the resistance heating current passage of the roller.
J3. A method as set forth in statement J1, further comprising unspooling a web of the electronics structure upstream from the roller.
J4. A method as set forth in statement J3, further comprising spooling the web of the electronics structure downstream from the roller.
J5. A method as set forth in statement J1, wherein moving the electronics structure across the roller causes the roller to turn.
J6. A method as set forth in statement J1, wherein heat is distributed across a surface of the roller to substantially uniformly heat the electronics structure along a length of the electronics structure.
J7. A method as set forth in statement J1, wherein heating the roller comprises passing the at least one pulse of current through an electrically conductive layer of the roller.
J8. A method as set forth in statement J1, wherein thermally processing the electronics structure comprises curing a curing layer supported by a web.
K1. A system for thermally processing an electronics structure, the system comprising:
a roller comprising an electrically conductive layer configured to generate heat by resistance heating when current is passed through the electrically conductive layer.
K2. A system as set forth in statement K1, wherein the roller comprises a tubular carrier body carrying the electrically conductive layer.
K3. A system as set forth in statement K2, wherein the electrically conductive layer is coated on the tubular carrier body.
K4. A system as set forth in statement K2, further comprising a tubular stage inside the tubular carrier body, the tubular stage electrically coupled to the electrically conductive layer.
K5. A system as set forth in statement K4, wherein the tubular stage is electrically coupled to the electrically conductive layer inside the tubular carrier body.
K6. A system as set forth in statement K2, wherein the electrically conductive layer includes an outer portion outside the tubular carrier body and an inner portion inside the tubular carrier body, the outer and inner portions of the electrically conductive layer being electrically coupled across a current source to provide an electrical loop through the electrically conductive layer.
K7. A system as set forth in statement K6, wherein the current source is configured to transmit a sequence of pulses of current through the electrically conductive layer.
K8. A system as set forth in statement K1, wherein the roller comprises a carrier body carrying the electrically conductive layer, the electrically conductive layer extending around a circumference of the carrier body.
K9. A system as set forth in statement K1, further comprising an unspooler upstream from the roller for supplying a web to the roller.
K10. A system as set forth in statement K9, further comprising a spooler downstream from the roller for spooling the web from the roller.
L1. A system for thermally processing an electronics structure supported by an electrically conductive carrier, the system comprising:
a stage for supporting the electrically conductive carrier; and
an inductor located with respect to the stage to induce an eddy current in the electrically conductive carrier when the electrically conductive carrier is supported by the stage; and
a current source configured to deliver at least one pulse of current to the inductor to induce the eddy current in the electrically conductive carrier for thermally processing the electronics structure carried by the electrically conductive carrier.
L2. A system as set forth in statement L1, wherein the current source is configured to deliver a sequence of pulses of current to the inductor to cause eddy currents in the electrically conductive carrier.
L3. A system as set forth in statement L2, wherein the current source comprises a capacitor bank.
L4. A system as set forth in statement L1, in combination with the electrically conductive carrier.
M1. A method of thermally processing an electronics structure, the method comprising:
energizing an inductor located with respect to an electrically conductive carrier to cause eddy currents in the electrically conductive carrier for thermally processing an electronics structure temporarily carried by the electrically conductive carrier by heating the electronics structure.
M2. A method as set forth in statement M1, wherein energizing the inductor comprises discharging a pulse of current across the inductor.
M3. A method as set forth in statement M1, wherein energizing the inductor comprises discharging sequential pulses of current across the inductor.
M4. A method as set forth in statement M1, wherein thermally processing the electronics structure comprises curing a film carried by the electrically conductive carrier.
M5. A method as set forth in statement M1, wherein thermally processing the electronics structure comprises heating an adhesive to loosen the adhesive to permit removal of an electronics structure substrate from the electrically conductive carrier.
N1. A method of thermally processing an electronics structure, the method comprising:
providing an electrically conductive carrier temporarily carrying an electronics structure, wherein the electrically conductive carrier is adhesively bonded to the electronics structure using an electrically conductive adhesive; and passing an electrical current through at least a first electrically conductive portion of the electrically conductive carrier to the electrically conductive adhesive to generate heat in the electrically conductive adhesive for debonding the electronics structure from the electrically conductive carrier.
N2. A method as set forth in statement N1, further comprising removing the electronics structure from the electrically conductive carrier after heating the adhesive.
P1. A carrier for temporarily carrying an electronics structure for processing, the carrier comprising:
an electrical contact side of the carrier;
a working side of the carrier opposite the electrical contact side;
an electronics structure support surface on the working side configured to support the electronics structure temporarily for processing of the electronics structure;
a carrier body having a first side on the electrical contact side of the carrier and an opposite second side on the working side of the carrier, the carrier body having a peripheral edge between the first and second sides;
a first electrical contact on the electrical contact side and supported by the carrier body;
a second electrical contact on the electrical contact side and supported by the carrier body;
a first resistance heating current passage on the working side of the carrier and supported by the carrier body;
a first current pathway extending over the peripheral edge of the carrier body from the first side to the second side, the first current pathway electrically coupling the first resistance heating current passage with the first electrical contact;
a second current pathway extending over the peripheral edge of the carrier body from the first side to the second side, the second current pathway electrically coupling the first resistance heating current passage with the second electrical contact; and
wherein the first resistance heating current passage is configured to generate heat via current passed through the first resistance heating current passage via the first and second electrical contacts.
P2. A carrier as set forth in statement P1, wherein the first resistance heating current passage is configured to direct current flow along a length of the first resistance heating current passage, the first resistance heating current passage having a width transverse to the length, the width being greater than a thickness of the first resistance heating current passage.
P3. A carrier as set forth in statement P1, wherein the first resistance heating current passage is configured to create distributed heat across a width of the first resistance heating current passage, the width being greater than a thickness of the first resistance heating current passage.
P4. A carrier as set forth in statement P1, wherein the first electrical contact is electrically isolated on the electrical contact side from the second electrical contact.
P5. A carrier as set forth in statement P1, further comprising an electrically conductive layer, the electrically conductive layer defining the first resistance heating current passage, the first current pathway, and the second current pathway.
P6. A carrier as set forth in statement P5, wherein the electrically conductive layer defines the first electrical contact and the second electrical contact.
P7. A carrier as set forth in statement P5, wherein the electrically conductive layer wraps around the peripheral edge of the carrier body between the first resistance heating current passage and the first electrical contact and between the first resistance heating current passage and the second electrical contact.
P8. A carrier as set forth in statement P1, wherein the first electrical contact is electrically coupled to the first resistance heating current passage via a third current pathway in parallel with the first current pathway.
P9. A carrier as set forth in statement P8, further comprising an electrically conductive layer on the electrical contact side of the carrier body, the electrically conductive layer defining the first and second current pathways, the first and second current pathways being electrically separated from each other by electrically isolating breaks in the electrically conductive layer.
P10. A carrier as set forth in statement P9, further comprising a second resistance heating current passage on the working side of the carrier, the second resistance heating current passage being configured to generate heat via current passed therethrough.
P11. A carrier as set forth in statement P10, wherein the second resistance heating current passage is electrically coupled to the first electrical contact.
P12. A carrier as set forth in statement P10, further comprising a third electrical contact on the electrical contact side of the carrier, the third electrical contact being electrically isolated from the first electrical contact, the second resistance heating current passage being electrically coupled to the third electrical contact.
P13. A carrier as set forth in statement P12, further comprising a fourth electrical contact on the electrical contact side of the carrier, the fourth electrical contact being electrically isolated form the first electrical contact, the second resistance heating current passage being electrically coupled to the fourth electrical contact.
P14. A carrier as set forth in statement P13, further comprising an electrically conductive layer on the working side of the carrier, the electrically conductive layer defining the first and second resistance heating current passages, the first and second resistance heating current passages being separated from each other by an electrically isolating break in the electrically conductive layer.
P15. A carrier as set forth in statement P1, further comprising a second resistance heating current passage on the working side of the carrier, the second resistance heating current passage being configured to generate heat via current passed therethrough.
P16. A carrier as set forth in statement P15, further comprising an electrically conductive layer on the working side of the carrier, the electrically conductive layer defining the first and second resistance heating current passages, the first and second resistance heating current passages being separated by a first electrically isolating break in the electrically conductive layer.
P17. A carrier as set forth in statement P16, wherein the first and second electrical contacts are separated by a second electrically isolating break on the electrical contact side, the first electrically isolating break extending crosswise with respect to the second electrically isolating break.
P18. A carrier stack comprising the carrier of statement P1 and the electronics structure, the electronics structure being adhesively bonded to the working side of the carrier.
P19. A carrier stack comprising the carrier of statement P1 in combination with the electronics structure, the electronics structure comprising a cured film on the working side of the carrier.
P20. A carrier as set forth in statement P1, further comprising a dielectric layer on the working side of the carrier, the dielectric layer separating the first resistance heating current passage from the electronics structure support surface.
P21. A carrier as set forth in statement P1, wherein the first resistance heating current passage defines at least part of the electronics structure support surface.
P22. A carrier as set forth in statement P1, further comprising a dielectric layer, the carrier body carrying the dielectric layer, the dielectric layer being between the carrier body and the first resistance heating current passage.

What is claimed is:

1. A carrier for temporarily carrying an electronics structure for processing, the carrier comprising:
an electrical contact side of the carrier;
a working side of the carrier opposite the electrical contact side;
an electronics structure support surface on the working side configured to support the electronics structure temporarily for processing of the electronics structure;
a carrier body having a first side on the electrical contact side of the carrier and an opposite second side on the working side of the carrier, the carrier body having a peripheral edge between the first and second sides;
a first electrical contact on the electrical contact side and supported by the carrier body;
a second electrical contact on the electrical contact side and supported by the carrier body;
a first resistance heating current passage on the working side of the carrier and supported by the carrier body;
a first current pathway extending over the peripheral edge of the carrier body from the first side to the second side, the first current pathway electrically coupling the first resistance heating current passage with the first electrical contact;
a second current pathway extending over the peripheral edge of the carrier body from the first side to the second side, the second current pathway electrically coupling the first resistance heating current passage with the second electrical contact; and
wherein the first resistance heating current passage is configured to generate heat via current passed through the first resistance heating current passage via the first and second electrical contacts.

2. A carrier as set forth in claim 1, wherein the first resistance heating current passage is configured to direct current flow along a length of the first resistance heating current passage, the first resistance heating current passage having a width transverse to the length, the width being greater than a thickness of the first resistance heating current passage.

3. A carrier as set forth in claim 1, wherein the first resistance heating current passage is configured to create distributed heat across a width of the first resistance heating current passage, the width being greater than a thickness of the first resistance heating current passage.

4. A carrier as set forth in claim 1, wherein the first electrical contact is electrically isolated on the electrical contact side from the second electrical contact.

5. A carrier as set forth in claim 1, further comprising an electrically conductive layer, the electrically conductive layer defining the first resistance heating current passage, the first current pathway, and the second current pathway.

6. A carrier as set forth in claim 5, wherein the electrically conductive layer defines the first electrical contact and the second electrical contact.

7. A carrier as set forth in claim 5, wherein the electrically conductive layer wraps around the peripheral edge of the carrier body between the first resistance heating current passage and the first electrical contact and between the first resistance heating current passage and the second electrical contact.

8. A carrier as set forth in claim 1, wherein the first electrical contact is electrically coupled to the first resistance heating current passage via a third current pathway in parallel with the first current pathway.

9. A carrier as set forth in claim 8, further comprising an electrically conductive layer on the electrical contact side of the carrier body, the electrically conductive layer defining the first and second current pathways, the first and second current pathways being electrically separated from each other by electrically isolating breaks in the electrically conductive layer.

10. A carrier as set forth in claim 9, further comprising a second resistance heating current passage on the working side of the carrier, the second resistance heating current passage being configured to generate heat via current passed therethrough.

11. A carrier as set forth in claim 10, wherein the second resistance heating current passage is electrically coupled to the first electrical contact.

12. A carrier as set forth in claim 10, further comprising a third electrical contact on the electrical contact side of the carrier, the third electrical contact being electrically isolated from the first electrical contact, the second resistance heating current passage being electrically coupled to the third electrical contact.

13. A carrier as set forth in claim 12, further comprising a fourth electrical contact on the electrical contact side of the carrier, the fourth electrical contact being electrically isolated form the first electrical contact, the second resistance heating current passage being electrically coupled to the fourth electrical contact.

14. A carrier as set forth in claim 13, further comprising an electrically conductive layer on the working side of the carrier, the electrically conductive layer defining the first and second resistance heating current passages, the first and second resistance heating current passages being separated from each other by an electrically isolating break in the electrically conductive layer.

15. A carrier as set forth in claim 1, further comprising a second resistance heating current passage on the working side of the carrier, the second resistance heating current passage being configured to generate heat via current passed therethrough.

16. A carrier as set forth in claim 15, further comprising an electrically conductive layer on the working side of the carrier, the electrically conductive layer defining the first and second resistance heating current passages, the first and second resistance heating current passages being separated by a first electrically isolating break in the electrically conductive layer.

17. A carrier as set forth in claim 16, wherein the first and second electrical contacts are separated by a second electrically isolating break on the electrical contact side, the first electrically isolating break extending crosswise with respect to the second electrically isolating break.

18. A carrier stack comprising the carrier of claim 1 and the electronics structure, the electronics structure being adhesively bonded to the working side of the carrier.

19. A carrier stack comprising the carrier of claim 1 in combination with the electronics structure, the electronics structure comprising a cured film on the working side of the carrier.

20. A carrier as set forth in claim 1, further comprising a dielectric layer on the working side of the carrier, the dielectric layer separating the first resistance heating current passage from the electronics structure support surface.

21. A carrier as set forth in claim 1, wherein the first resistance heating current passage defines at least part of the electronics structure support surface.

22. A carrier as set forth in claim 1, further comprising a dielectric layer, the carrier body carrying the dielectric layer, the dielectric layer being between the carrier body and the first resistance heating current passage.
